(19) United States
(12) Patent Application Publication
(10) Pub. No.: US 2024/0231489 A1
(43) Pub. Date: Jul. 11, 2024

(54) WEARABLE INTERFACE DEVICES WITH TACTILE FUNCTIONALITY

(71) Applicant: CORNELL UNIVERSITY, Ithaca, NY (US)

(72) Inventors: Hsin-Liu Kao, Ithaca, NY (US); Heather Kim, Ithaca, NY (US); Kunpeng Huang, Ithaca, NY (US); Ruojia Sun, Ithaca, NY (US); Jeyeon Jo, Ithaca, NY (US)

(21) Appl. No.: 18/559,544

(22) PCT Filed: May 9, 2022
(86) PCT No.: PCT/US22/28340

§ 371 Date: Nov. 7, 2023

Related U.S. Application Data
(60) Provisional application No. 63/185,908, filed on May 7, 2021.
(60) Provisional application No. 63/213,647, filed on Jun. 22, 2021.

(51) Int. Cl. G06F 3/01; G06F 1/16; G06F 3/044; H02J 50/00; H04W 4/02

(52) U.S. Cl. CPC G06F 3/014; G06F 1/163; G06F 3/016; G06F 3/044; H02J 50/001; H04W 4/025; G06F 2203/04105

(57) ABSTRACT

This technology is directed to wearable on-skin interface devices comprising a textile structure with components that function to detect environmental inputs and provide outputs as responses. The textile structure is a woven or knitted texture structure with circuitry, sensors, and actuators incorporated into the textile structure for electrical connections between the layers while maintaining a slim form. The wearable on-skin interface devices comprise a microprocessor that receives inputs from the sensors and uses the inputs to initiate response functions from the actuators. Conductive materials may be woven into the textile structure to establish electrical connections between adjoining layers of the interlaced materials to form one or more electrical vertical access structures.

### CROSS-REFERENCE TO RELATED APPLICATIONS

This application claims the benefit of and priority to U.S. Provisional Patent Application No. 63/185,908, filed May 7, 2021 entitled “Woven On-Skin Electronic Devices And Methods Of Fabricating The Same”, and U.S. Provisional Patent Application No. 63/213,647, filed Jun. 22, 2021 entitled “Woven On-Skin Electronic Devices And Methods Of Fabricating The Same”, the contents of which are incorporated by reference in their entireties herein.

### TECHNICAL FIELD

This disclosure relates to textile-based wearable on-skin interface devices with tactile functionality.

### BACKGROUND

Electronic devices have undergone dramatic transformations over the last several decades. As electronic devices are increasingly being used throughout the day for various tasks, new form factors are being developed. Form factors have been developed that use the human skin as an interface to facilitate human-computer interactions (“HCl”). Conventional on-skin interfaces are created through digital fabrication approaches including laser-cutting, lamination, and inkjet printing, or through craft techniques such as screen-printing and stenciling. The expressive and material qualities of conventional on-skin interfaces are largely limited to color and graphic customization. Conventional on-skin interfaces have not implemented complex circuit typography such as electrical vertical access structures (“VIAS”), integrated novel functional materials, or incorporated aesthetic qualities such as textures and unusual materials.

Conventional on-skin interfaces may be silicone based, such as Polydimethylsiloxane (“PDMS”), because silicone is flexible, soft, stretchable, and may enclose electronics. However, PDMS is not breathable. PDMS covers the skin surface completely such that air and/or moisture cannot pass through, which creates discomforts to users, especially when larger son-skin interfaces are applied. In addition, thin PDMS structures, which may afford a user more comfort, are typically not re-usable and lack in the sturdiness and stability to withstand regular wear and tear for longer periods.

Conventional on-skin interfaces may include tactile interfaces. While tactile interfaces have utilized skin as an area for haptic input, bulky form factors and complicated mechanical systems have hindered wider utilization of body locations. Form factors in such interfaces are contained to wristbands, limiting application to only the forearm. Moreover, complexity in mechanical design allows little compatibility across different tactile feedback, encumbering both user and designers. Conventional methods for high-resolution tactile outputs are often bulky and not body conformable. Conventional methods often require rigid devices (i.e., pumps or compressors), which may not be wearable and can constrain the use of conventional on-skin interfaces to certain body locations. Each tactile output often requires distinct actuation mechanisms, making it challenging to combine different techniques for designing richer haptic sensations. The lack of skin conformity and versatile actuation mechanism in current tactile devices limits their expressiveness.

Additionally, interactive devices in HCl have predominantly been static or fixed in one location. Mobility in conventional devices is enabled by rigid appendages such as grippers, magnetic wheels, and spikes, and accordingly are not suitable for on-skin application. Conventional mobile interface devices lack the use of pliable materials.

### BRIEF DESCRIPTION OF THE DRAWINGS

FIG. 1 is a block diagram depicting a wearable device system.

FIG. 2 is a block diagram depicting a wirelessly charged wearable device system.

FIG. 3 is a perspective view of a hand-mounted wearable device.

FIG. 4 is a perspective view of a wirelessly charged hand-mounted wearable device.

FIGS. 5A-5B, where FIG. 5A is a perspective view of an example placement of a wirelessly charged hand-mounted wearable device on a user's hand, and FIG. 5B is an illustration depicting example weave technology for a wearable device.

FIG. 6A, FIG. 6B, and FIG. 6C are illustrations depicting the 5-dimensional design space of a wearable device.

FIG. 7A, FIG. 7B, FIG. 7C, and FIG. 7D depict an example embodiment of a wearable device with a capacitive touch sensor and a thermochromic display.

FIG. 8A, 8B, 8C, and 8D depict an example embodiment of a wearable device with a pressure sensor and a haptic actuator.

FIG. 9A, 9B, and 9C depict an example embodiment of a wearable device with 3-dimensional electrical connections between layers.

FIG. 10A, FIG. 10B, and FIG. 10C depict examples of embodiments of a wearable device with functional weave material.

FIG. 11A, FIG. 11B, FIG. 11C, and FIG. 11D depict example embodiments of wearable devices with aesthetic dimensionality.

FIG. 12A, FIG. 12B, FIG. 12C, and FIG. 12D, depict example embodiments of a wearable device comprising a manufactured fabric.

FIG. 13A, FIG. 13B and FIG. 13C depict example tactile actuation design factors.

FIG. 14A, FIG. 14B, and FIG. 14C depict knit structure design factors.

FIG. 15A, FIG. 15B, FIG. 15C, FIG. 15D, FIG. 15E, FIG. 15F, FIG. 15G, FIG. 15H, FIG. 15I, FIG. 15J, FIG. 15K, FIG. 15L, FIG. 15M, FIG. 15N, and FIG. 15O depict use cases for a knitted form factor for wearable devices.

FIG. 16A and FIG. 16B depict example use cases for wearable devices.

FIG. 17A and FIG. 17B depict perspective views of a locomotion wearable device.

FIG. 18 depicts a knitted structure to form a scaled substrate of a locomotion wearable device.

FIG. 19 depicts example geometric parameters of scales.

FIG. 20A and FIG. 20B depict an example use case of a locomotion wearable device.

FIG. 21A and FIG. 21B depict an industrial application use case of a locomotion wearable device.

FIG. 22A and FIG. 22B depict an agricultural application use case of a locomotion wearable device.

FIG. 23 depicts a bendable patch wearable device.

FIG. 24 depicts an expandable patch wearable device.

FIG. 25 depicts a shrinkable patch wearable device.

FIG. 26 is a block diagram depicting a computing machine and a module.

### DETAILED DESCRIPTION

### Overview

The present technology is directed towards textile-based, wearable on-skin interface devices with tactile functionality. The wearable on-skin interface may be used to recognize hand gestures, provide feedback in response to device notification, or provide haptic feedback in response to a variety of sensor inputs. The wearable on-skin interface device has embedded circuitry and components including one or more of a battery, a memory, an energy harvester, a microprocessor, sensors, and actuators. In an example, the wearable on-skin interface device may not include a battery and may be capable of wireless charging by near field communication (“NFC”) capabilities. The components are interconnected by one or more conductors to create a circuit.

The wearable on-skin interface device is a textile structure with components that function to detect environmental inputs and provide outputs as responses. In an example, the microprocessor may be configured to receive inputs from the sensors and use the inputs to determine one or more of a spatial location, configuration, or orientation of the sensors. The one or more of a spatial location, configuration, or orientation of the sensors may be used to track movements of a user, such as in an avatar application or during a sporting event. The one or more of a spatial location, configuration, or orientation of the sensors may be used as a navigation tool, such as a global positioning system (“GPS”) navigation or a navigation tool for a person with impaired vision. In an example, the microprocessor may receive inputs from the sensors and use the inputs to track vital signs or signals in health care related application. In an example, the microprocessor may receive inputs from the sensors and use the inputs to initiate a response function from the actuators.

The textile structure may be a woven textile structure with one or more layers of interlaced materials. Weaving enables circuitry to be incorporated into the textile structure for electrical connections between the layers while maintaining a slim form. Weaving provides two- and three-dimensional structural capabilities for integration of complex circuit typology with a broad selection of materials and diverse textures. The components of the wearable on-skin interface device may be embedded within the layers of the interlaced materials. The interlaced materials include weft and yarns (or materials) with either the weft or the warp material being a conductive material to serve as the conductor within the wearable on-skin interface device. The conductive material of the weft or warp material functions to establish electrical connections between adjoining layers of the interlaced materials to form one or more electrical vertical access structures (“VIAS”).

The textile structure may also be a knitted textile structure with one or more channels within the knitted structure. The components of the wearable on-skin interface device may be embedded within the channels of the knitted structure.

The wearable on-skin interface device may be configured to be affixed to a user or an object by an adhesive layer, or as a sleeve configuration to be affixed by compression. The wearable on-skin interface device may have fasteners, clips, or other suitable mechanisms to be affixable to the user. The wearable on-skin interface device may be a garment or other article of clothing that is wearable by a user.

The wearable on-skin interface device includes a 5-dimensional design space. The 5-dimensional design space is achieved through a combination of weave structure, functional dimensionality, and aesthetic dimensionality. The wearable on-skin interface device may be configured with skin-shifting actuation or self-shifting actuation.

The wearable on-skin interface device is configurable for various types of skin topographies. Tactile feedback can be customized according to an underlying skin topography or body landmark. Tactile interfaces can be designed for placement on planar body parts (e.g., back of hand), cylindrical body parts (e.g., forearm), protruded body joints (e.g., elbow, knees, and knuckles), and concave body locations (e.g., the purlicue, armpit, and Achilles tendon arch).

The wearable on-skin interface device may be configured for motion, or locomotion, relative to a surface to which the wearable on-skin interface device is placed. A locomotion wearable device is a soft and coordinated system configured to transverse or “crawl” cylindrical surfaces or objects. The locomotion wearable device is a sleeve-type, conformable form factor that exhibits anisotropic friction while in motion. The locomotion wearable device exerts a normal force to the cylindrical surface to which the device is affixed such that the device can transverse cylindrical surfaces in a longitudinal direction without slipping.

The wearable on-skin interface device may be configured as a patch wearable device, with functionality including bending, expanding, and shrinking. A patch wearable device is a deformable interface devised as a woven patch that enables diverse movement-based interactions adaptive to garments or on-skin wearing. The patch wearable device is a detachable and relocatable actuation unit that can be sewn or attached to clothing or skin at various locations. The patch wearable device integrates actuators at a structural level and varies the texture and stiffness of the woven substrate. The woven substrate is embedded with SMA actuators that is woven with unique structural and yarn material combinations to yields a versatile woven substrate tunable for different actuation mechanisms. Taking advantage of the structural and textural flexibility of weaving, the patch wearable device enables slim integration while preserving expressive weave aesthetics.

These and other aspects, objects, features, and advantages of the disclosed technology will become apparent to those having ordinary skill in the art upon consideration of the following detailed description of illustrated examples.

### Example System Architecture

Turning now to the drawings, in which like numerals indicate like (but not necessarily identical) elements throughout the figures, examples of the technology are described in detail.

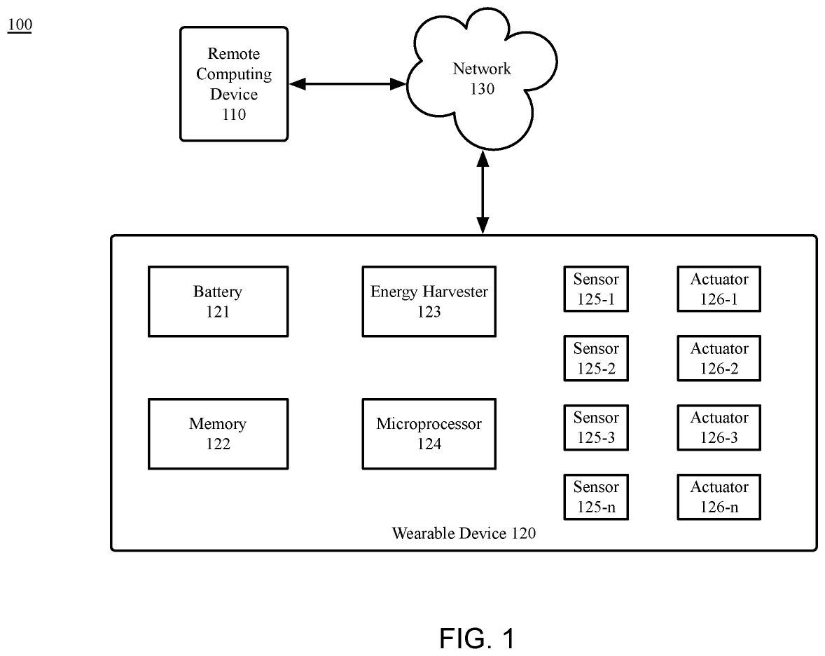

FIG. 1 is a block diagram depicting a wearable device system 100, in accordance with certain examples. As depicted in FIG. 1, the wearable device system 100 comprises a remote computing device 110 and a wearable device 120. Remote computing device 110 and wearable device 120 are configured to communicate via a network 130.

In example embodiments, network 130 includes one or more wired or wireless telecommunications systems by which network devices may exchange data. For example, the network 130 may include one or more of a local area network (LAN), a wide area network (WAN), an intranet, an Internet, a storage area network (SAN), a personal area network (PAN), a metropolitan area network (MAN), a wireless local area network (WLAN), a virtual private network (VPN), a cellular or other mobile communication network, a BLUETOOTH® wireless technology connection, a near field communication (NFC) connection, any combination thereof, and any other appropriate architecture or system that facilitates the communication of signals, data, and/or messages.

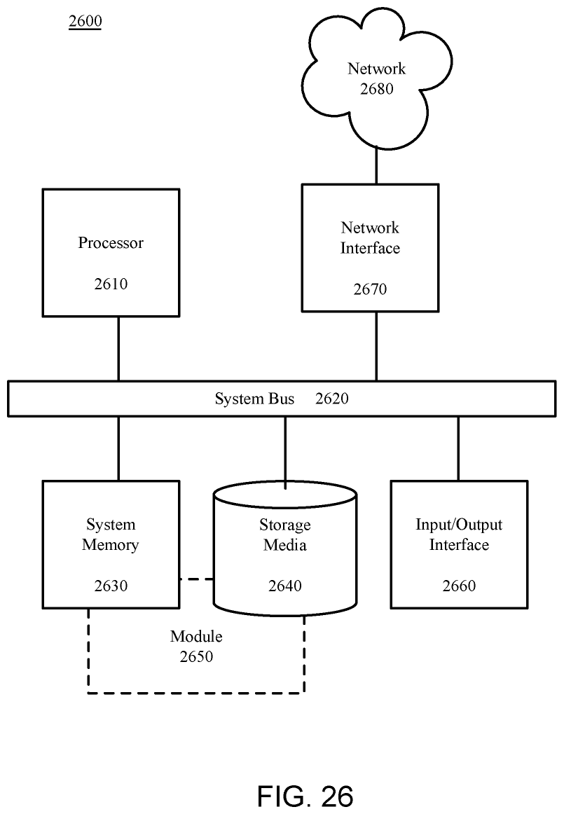

Remote computing device 110 may be any type of computing machine, such as, but not limited to, those discussed in more detail with respect to FIG. 26. For example, remote computing device 110 can include any suitable processor-driven device.

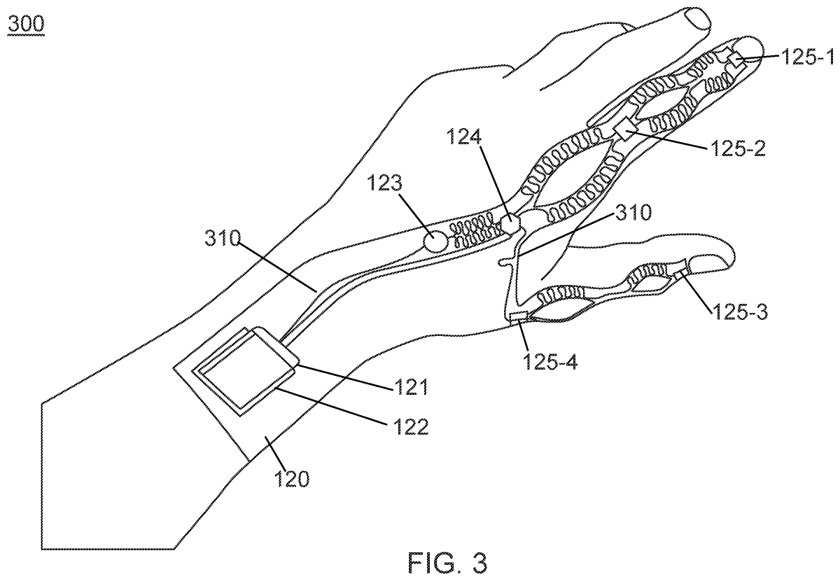

Wearable device 120 comprises a battery 121, a memory 122, an energy harvester 123, a microprocessor 124, sensors 125, and actuators 126. Battery 121, memory 122, energy harvester 123, microprocessor 124, sensors 125, and actuators 126 are interconnected by one or more conductors 310 (as described herein in reference to FIG. 3) within wearable device 120 such that a circuit is formed. Wearable device 120 is a textile structure comprising components that function to detect one or more inputs from the environment in which wearable device 120 is located and provide a response to the one or more inputs. In an example, the textile structure is a slim form factor. For example, a thickness of the textile structure may be in a range of 0.1 mm to 5 mm, with a preferred thickness of 0.1 mm to 1 mm. The thickness of the textile structure may be less than 0.1 mm, 0.5 mm, 1 mm, 2 mm, or any other suitable dimension such that the textile structure is a slim form factor. In an example, an area of wearable device 120 is proportional to an area of a location to which wearable device 120 is affixed. For example, the area of a wearable device 120 may be smaller when designed to be affixed to a wrist of a user as compared to the area of a wearable device 120 designed to be affixed to a knee of a user. In an example, wearable device 120 may be configured in a plurality of shapes. For example, wearable device 120 may be triangular, a square shape, rectangular, polygonal, circular, an irregular shape, a band, a ring, or any other suitable shape or combination of shapes. In an example, wearable device 120 may be configured as a patch, a bandage, a ring, a band, a garment, or any wearable textile. In an example, wearable device 120 is a soft, wearable computer, such as a “smart” wearable device. In an example, the textile structure may be a woven texture structure with one or more layers of interlaced materials. Weaving enables circuitry to be incorporated into the textile structure for electrical connections between the layers while maintaining a slim form. Weaving provides two- and three-dimensional structural capabilities for integration of complex circuit typology with a broad selection of materials and diverse textures. Battery 121, memory 122, energy harvester 123, microprocessor 124, sensors 125, and actuators 126 of the wearable device 120 may be embedded within the layers of the interlaced materials. The interlaced materials comprise a weft material and a warp material. One of the weft material or warp material may be a conductive material that functions as a conductor within wearable device 120. The conductor functions to distribute power within wearable device 120. In an example, the conductive material may be 34 gauge copper wire, 38 gauge copper wire, or any other suitable conductive material.

The conductive material of the weft material or the warp material functions to establish electrical connections between adjoining layers of the interlaced materials. The electrical connections between the adjoining layers of the interlaced materials form one or more electrical vertical access structures (“VIAS”) within the textile structure.

In an example, the textile structure may be a knitted textile structure with one or more channels within the knitted structure. Battery 121, memory 122, energy harvester 123, microprocessor 124, sensors 125, and actuators 126 of wearable device 120 may be embedded within the channels of the knitted structure.

In an example, wearable device 120 may be configured to be affixed to a user. Wearable device 120 may comprise an adhesive layer such that wearable device 120 may be affixed to a location on a user. In an example, the adhesive layer may be a polyvinyl alcohol adhesive, an eyelash glue, a medical prosthetic adhesive, a nail adhesive, or any other suitable adhesive to affix wearable device 120 to a user. Wearable device 120 may be configured as a sleeve that may slide onto the user such that the wearable device is affixed to the user by compression. Wearable device 120 may comprise fasteners, clips, or any other suitable mechanism to affix wearable device 120 to the user. Wearable device 120 may be a garment or other article that is wearable by a user. For example, wearable device 120 may be a shirt, pants, glove, sock, hair piece, or any other suitable garment or article wearable by a user. Wearable device 120 may be affixed to the skin of the user, the hair of the user, a garment of the user, or any suitable location such that wearable device 120 may detect one or more inputs from the environment in which wearable device 120 is located and provide a response to the one or more inputs.

In an example, wearable device 120 may be configured to be affixed to a location on an object, an agricultural product, or any other suitable application such that wearable device 120 may detect one or more inputs from the environment in which wearable device 120 is located and provide a response to the one or more inputs. Embodiments of wearable device 120 will be discussed in greater detail herein with respect to FIGS. 3 through 25.

Wearable device 120 comprises battery 121. Battery 121 functions to provide power to the components of wearable device 120. While FIG. 1 depicts a single battery 121, wearable device 120 may comprise one or more batteries 121 to provide power to the components of wearable device 120. Battery 121 has a small form factor battery such that battery 121 may be embedded within the one or more interlaced layers or channels of wearable device 120. In an example, battery 121 provides power to the components of wearable device 120 via one or more conductors embedded within wearable device 120, not depicted in FIG. 1. In an example, battery 121 is a lithium polymer battery. In an example, wearable device 120 is configured such that battery 121 may be replaced. In an example, battery 121 is a rechargeable battery. Battery 121 may be charged by a connection to a charging station or battery 121 may be wirelessly charged. Battery 121 may be any battery suitable to provide power to the components of wearable device 120. In an alternate example, wearable device 120 may comprise a triboelectric nanogenerator to provide power to the components of wearable device 120.

Wearable device 120 comprises memory 122. Memory 122 functions to store data associated with inputs from sensors 125. In an example, microprocessor 124 receives inputs from sensors 125 and stores data associated with the inputs in memory 122. In an example, memory 122 has a small form factor such that memory 122 may be embedded within the one or more interlaced layers or channels of wearable device 120. In an example, memory 122 may be stacked on top of battery 121 within the one or more interlaced layers of wearable device 120. In an example, memory 122 may be a removable memory such as a Secure Digital (“SD”) card. Memory 122 may be any suitable memory capable of storing data associated with the inputs from sensors 125.

Wearable device 120 comprises energy harvester 123. Energy harvester 123 functions as power management for wearable device 120. In an example, battery 121 connects to energy harvester 123. Energy harvester 123 may function as a voltage regulator for battery 121. In an example, energy harvester 123 may provide a low power direct current to direct current (“DC-DC”) boost charge, store energy, charge and protect battery 121, be programmable to regulate power output, and be programmable to extract energy from external energy sources. In an example, energy harvester 123 has near-field communication (“NFC”) capabilities. In an example, energy harvester 123 has a small form factor such that energy harvester 123 may be embedded within the one or more interlaced layers or channels of wearable device 120.

Wearable device 120 comprises microprocessor 124. Microprocessor 124 may be configured to monitor and control the operation of the components in the wearable device 120. Microprocessor 124 may be a general purpose processor, a processor core, a multiprocessor, a reconfigurable processor, a microcontroller, a printed circuit board (“PCB”), a digital signal processor (“DSP”), an application specific integrated circuit (“ASIC”), a graphics processing unit (“GPU”), a field programmable gate array (“FPGA”), a programmable logic device (“PLD”), a controller, a state machine, gated logic, discrete hardware components, any other processing unit, or any combination or multiplicity thereof. Microprocessor 124 may be a single processing unit, multiple processing units, a single processing core, multiple processing cores, special purpose processing cores, co-processors, or any combination thereof. Microprocessor 124 may be powered by battery 121.

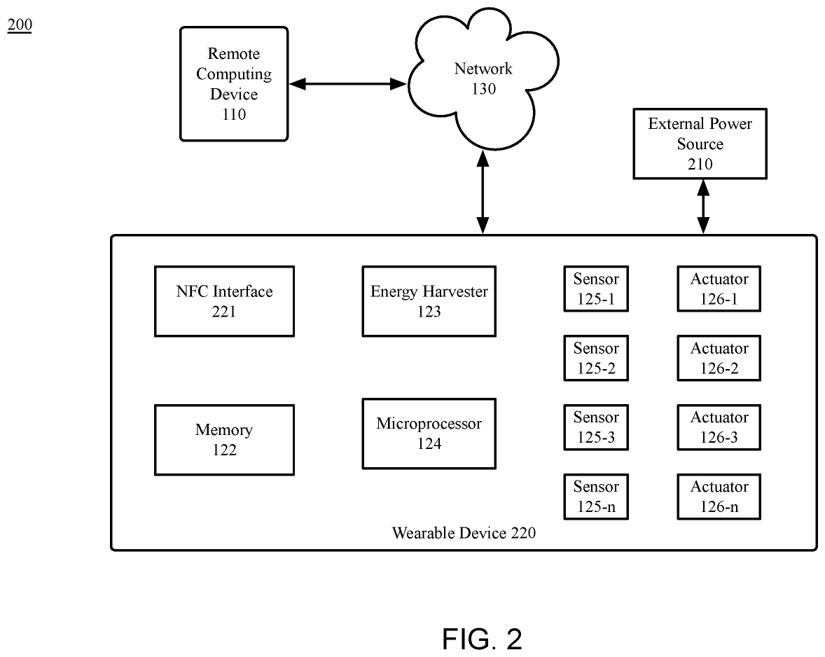

In an example, microprocessor 124 has a small form factor such that microprocessor 124 may be embedded within the one or more interlaced layers or channels of wearable device 120. In an example, microprocessor 124 may comprise one or more Inter-Integrated Circuit (“I2C”) interfaces to interface with sensors 125. In an example, microprocessor 124 may comprise one or more serial peripheral interfaces (“SPI”) for communications with NFC interface 221 (discussed herein with reference to FIG. 2) and memory 122. In an example, microprocessor 124 may be configured to communicate with external computing systems or other computing devices by a radio frequency identification (“RFID”) signal, for example, remote computing device 110. In an example, microprocessor 124 may be configured to communicate with external computing systems or other computing devices via Bluetooth, for example, remote computing device 110.

Microprocessor 124 may be configured to receive inputs from sensors 125 for processing. In an example, microprocessor 124 may receive inputs from sensors 125 and use the inputs to determine one or more of a spatial location, configuration, or orientation of the sensors 125 of wearable device 120. The one or more of a spatial location, configuration, or orientation of the sensors 125 may be used to track movements of a user, such as in an avatar application or during a sporting event. The one or more of a spatial location, configuration, or orientation of the sensors 125 may be used as a navigation tool, such as a global positioning system (“GPS”) navigation or a navigation tool for the blind. In an example, microprocessor 124 may receive inputs from sensors 125 and use the inputs to track vital signs or signals in health care related application. In an example, microprocessor 124 may receive inputs from sensors 125 and use the inputs to initiate a response function from actuators 126. For example, microprocessor 124 may transmit a signal to one or more actuators 126 to initiate the response function. In an alternate example, microprocessor 124 may be configured to receive inputs from sensors 125 and transmit data associated with the inputs to an external computing system, such as remote computing device 110, for further processing.

Wearable device 120 comprises sensors 125-1 through 125-n. Wearable device 120 may comprise a single sensor 125 or a plurality of sensors 125. Sensors 125 are components of wearable device 120 that detect one or more inputs from the environment in which wearable device 120 is located. In an example, each sensor 125 has a small form factor such that sensors 125 may be embedded within the one or more interlaced layers or channels of wearable device 120. Sensors 125 may be one or more of a capacitive touch sensor, a strain sensor, a pressure sensor, a biosensor, an inertial movement unit (“IMU”), a microphone, a water sensor, a velocity sensor, a resistive sensor, a physiological sensor, or any other suitable sensor to detect an input from the environment in which wearable device 120 is located. In an example, a biosensor may be configured to monitor or measure one or more of a temperature, blood pressure, pulse, or any other suitable biometric. In an example, an IMU may comprise a machine learning core to pre-process data and be configured to measure one or more of an acceleration, orientation, and angular movement rate.

Wearable device 120 comprises actuators 126-1 through 126-n. Actuators 126 may also be referred to as functional devices. Actuators 126 are components of wearable device 120 configured to provide a response function based on one or more signals from microprocessor 124 or inputs from one or more sensors 125. Wearable device 120 may comprise a single actuator 126 or a plurality of actuators 126. In an example, each actuator 126 has a small form factor such that actuators 126 may be embedded within the one or more interlaced layers or channels of wearable device 120. As used herein, an actuator comprises a device configured to change from a first state to a second state responsive to a first input. In some aspects, the actuator is further configured to change from the second state back to the first state responsive to a second input, which could be the same input as the first input or a different input than the first input. In some aspects, the actuator is configured to change from a first state to a particular one of a plurality of available states responsive to an input corresponding to that particular one of a plurality of available states. In some examples, the actuator is configured to cycle between a first state and a second state responsive to one or more inputs. In some examples, the actuator is biased toward a first state so that, following actuation of the actuator to change state from the first state to the second state, the actuator will automatically return to the first state under action of the bias. In some examples, actuators 126, in accord with at least some aspects of the present concepts, may include one or more of a haptic feedback component, a stiffness component, a thermochromic display, an illumination device, an audio device, a shape-memory alloy (“SMA”) device, an optical fiber, or any other suitable functional device. In an example, an actuator 126 may be comprised of either the weft or warp material. For example, the weft material may be an optical fiber with a response function of illumination. The response function of actuators 126 may comprise one or more of a force, a vibration, a motion, a variable-stiffness response, a color change, a light emittance, a thermal sensation, a skin-shifting actuation, a self-shifting actuation, a bending movement, an expanding movement, a shrinking movement, a deformation movement, a pinching movement, a brushing movement, a twisting movement, a lengthening movement, or any other suitable response function. In an example, the thermal sensation may be a warming sensation or a cooling sensation. For example, the haptic feedback component may be a SMA actuator configured to apply a force, a vibration, or a motion. The stiffness component may comprise a SMA actuator to enable variable-stiffness. The thermochromic display may comprise thermochromic yards configured for color change. The SMA device may comprise SMA micro-springs configured to function as skin-shifting actuators when attached to a skin location of a user or as a self-shifting actuator when in close contact to a skin location of a user. The SMA micro-springs may be configured to apply one or more of a compression, a pinch, a brush, or a twist.

While FIG. 1 shows, by way of example, sensor 125-1 to sensor 125-n and actuator 126-1 to actuator 126-n, where “n” can be any integer, the present concepts also include a dissimilar number of sensors 125 and actuators 126 such as, for example, sensor 125-1 to sensor 125-n and actuator 126-1 to actuator 126-m, where “n” and “m” can be any integer, with “n” and “m” being different from one another. For instance, a single sensor 125 could be ganged to actuate a plurality of actuators 126 so that the number of actuators 126 is greater than the number of sensors 125. In another example, a plurality of sensors 125 could be used to actuate a single actuator 126 responsive to only a particular combination of sensor inputs.

FIG. 2 is a block diagram depicting a wirelessly charged wearable device system 200, in accordance with certain examples. As depicted in FIG. 2, the wearable device system 200 comprises a remote computing device 110, an external power source 210, and a wearable device 220. Remote computing device 110 and wearable device 220 are configured to communicate via a network 130. Remote computing device 110 and network 130 were previously described herein with reference to FIG. 1.

Wirelessly charged wearable device system 200 comprises external power source 210. External power source 210 comprises an NFC transceiver such that external power source 210 may transmit power via RFID transmissions or other suitable transmission means to an NFC enabled device, such as wearable device 220.

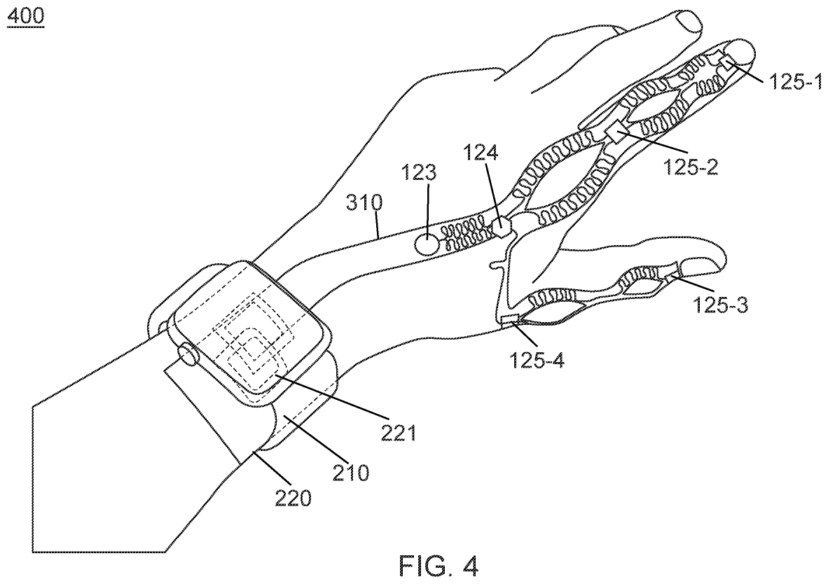

Wearable device 220 comprises an NFC interface 221, a memory 122, an energy harvester 123, a microprocessor or microcontroller 124, sensors 125, and actuators 126. Memory 122, energy harvester 123, microprocessor 124, sensors 125, and actuators 126 were previously described herein with reference to FIG. 1. Wearable device 220 has the same functionality as wearable device 120, previously described herein with reference to FIG. 1, with the exception that wearable device 220 has an NFC interface 221 to enable wireless charging capabilities. In an example, NFC interface 221 is an NFC coil embedded within the textile structure. NFC interface 221 enables wireless charging capabilities by functioning as an NFC transponder and receiving power from external power source 210. In an example, external power source 210 may be a smart watch or similar electronic device coupled with or comprising an NFC transceiver (as depicted herein with respect to FIG. 4) to enable wireless charging for wearable device 220. With wireless charging capabilities, wearable device 220 is capable of long-term continuous wear without battery replacement or a physical connection to a battery charging station.

FIG. 3 is a perspective view of a hand-mounted wearable device 300, in accordance with certain examples. The hand-mounted wearable device 300 is an example embodiment of wearable device 120. Hand-mounted wearable device 300 comprises wearable device 120 with a battery 121, a memory 122, an energy harvester 123, a microprocessor 124, sensors 125-1 through 125-4, and conductors 310. Conductors 310 may be 34 gauge copper wire, 38 gauge copper wire, or any other suitable conductive material to form a circuit between battery 121, memory 122, energy harvester 123, microprocessor 124, and sensors 125-1 through 125-4. The example embodiment of FIG. 3 depicts the wearable device 120 as an on-skin, glove-like interface form factor. Battery 121 and memory 122 are depicted in a stacked configuration.

In an example use case of wearable device 120 as depicted in FIG. 3, wearable device system 100 may function as a hand gesture recognition system. For example, wearable device system 100 may recognize hand gestures for sign language translation, augmented reality, or robotic control. In the example use case, sensors 125-1 through 125-4 are IMUs. The IMUs are used to track the thumb and index finger's motion. The IMUs are attached to phalanges of the hand where orientation of the hand is established. The sensors 125 are placed on the distal phalanx and metacarpal of the thumb and the index finger's distal and proximal phalanx. The IMUs are then connected to microcontroller 124, which can either be powered by a battery 121 (as described in reference to wearable device 120) or wirelessly receive power (as described in reference to wearable device 220) and transmit data through RFID via a pod-like device (i.e., external power source 210).

FIG. 4 is a perspective view of a wirelessly charged hand-mounted wearable device 400, in accordance with certain examples. The wirelessly charged hand-mounted wearable device 400 is an example embodiment of wearable device 220. Wirelessly charged hand-mounted wearable device 400 comprises wearable device 220 with a memory 122 (not depicted in FIG. 4), an energy harvester 123, a microprocessor 124, sensors 125-1 through 125-4, external power source 210, NFC interface 221, and conductors 310. The example embodiment of FIG. 4 depicts the wearable device 220 as an on-skin, glove-like interface form factor with an example use case as described herein with reference to FIG. 3.

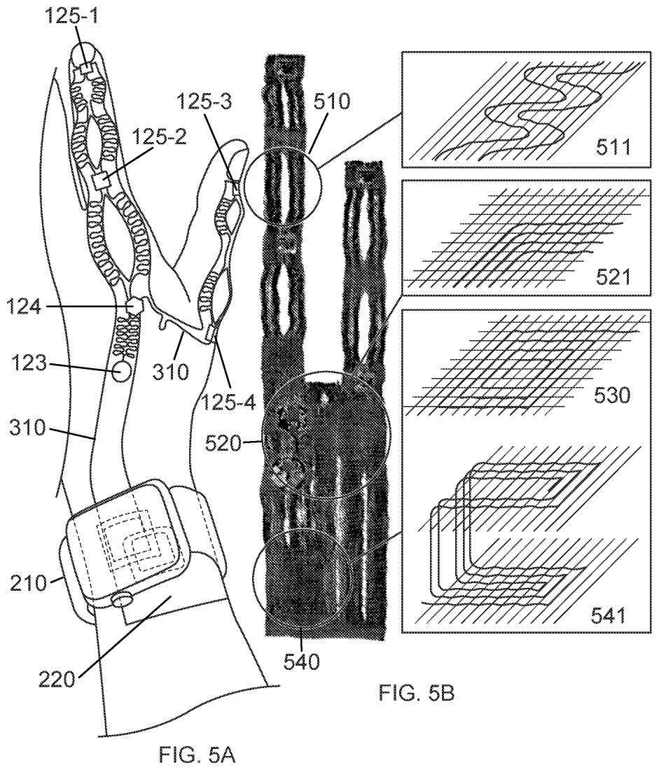

FIG. 5A is a perspective view of an example placement of a wirelessly charged hand-mounted wearable device 400 on a user's hand, in accordance with certain examples. The components of wirelessly charged hand-mounted wearable device 400 were previously described herein with reference to FIG. 4.

FIG. 5B is an illustration depicting example weave technology for a wearable device 120 or 220, in accordance with certain examples. Weave technologies offer structures that are highly durable and provide additional support for wearable device 120 and 220 components, as well as structures that are slimmer and more flexible, for increased compliance at body locations with challenging curvatures or that require flexing. A combination of weave technologies in a wearable device 120 or 220 allows for a textile structure that conforms to diverse body or object landmarks, seamlessly integrates spatially distributed electronic components into thin woven interfaces, and weaves complex functional elements into a wearable device 120 or 220.

A lace serpentine weave is illustrated at 510 with an enlargement at 511. A lace serpentine weave interlaces sections of warp and weft materials at non-orthogonal angles to expose regions of negative space and achieve a slim form, making a lace serpentine weave particularly suited for joints. A Manhattan routing weave is illustrated at 520 with an enlargement at 521. A Manhattan routing weave is a grid-like weave structure that routes weaving materials in horizontal and vertical directions. A Manhattan routing weave is advantageous in a wearable device 120 or 220 for effectively routing a complex network of distributed wearable device 120 and 220 components in a thin textile structure with groups of wires serving for a fully integrated electrical design. A tapestry coil weave is illustrated at 530. A tapestry coil weave is an advanced weaving technique that enables a variety of 2-dimensional and 3-dimensional circuit topographies, allowing for customization of a variety of wearable device 120 or 220 configurations and embodiments. A double weave coil is illustrated at 540 with an enlargement at 541. A double weave coil is an advanced weaving technique that enables a variety of 2-dimensional and 3-dimensional circuit topographies. A double weave coil can integrate circuits across multiple layers with VIAS.

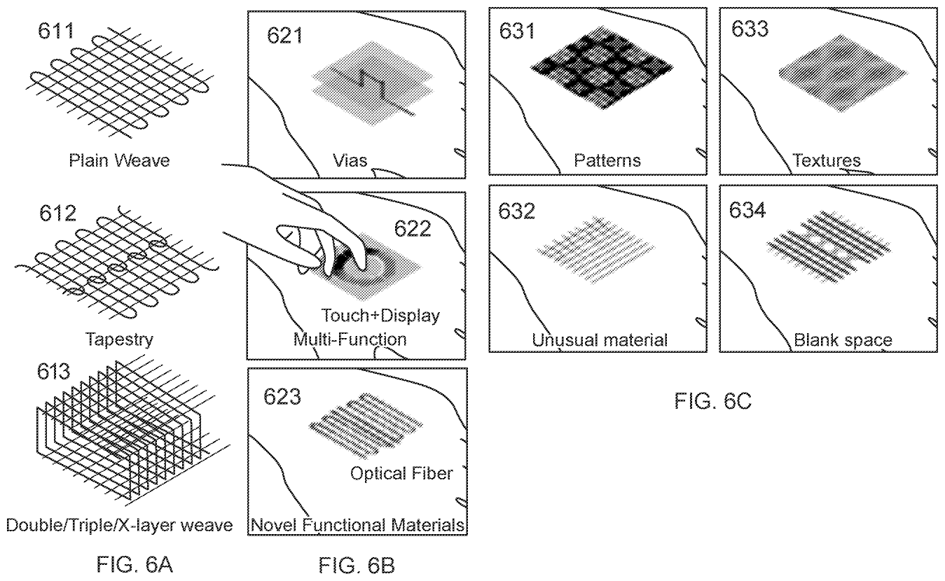

FIGS. 6A, 6B, and 6C are illustrations depicting the 5-dimensional design space of a wearable device 120 or 220, in accordance with certain examples. The 5-dimensional design space is achieved through a combination of weave structure, FIG. 6A, functional dimensionality, FIG. 6B, and aesthetic dimensionality, FIG. 6C. FIG. 6A depicts example weave structures to achieve 2 or 3 physical dimensions for wearable device 120 or 220. At 611, a plain weave structure is depicted. The plain weave structure is created by passing the weft material over and then under the adjacent warp material. At 612, a tapestry weave structure is depicted. The tapestry weave structure is a weft facing weave structure where the weft material may be discontinuous. At 613, a multiple layer weave structure is depicted. The multiple layer weave structure is a 3-dimensional structure with a layer-to-layer weave configuration. The multiple layer weave structure may be comprised of two layers, three layers, or more layers to achieve the desired design functionality for wearable device 120 or 220.

FIG. 6B depicts examples of functional dimensionality for wearable device 120 or 220. At 621, a VIAS created within the weave structure is depicted. As previously discussed herein, the conductive material of the weft material or the warp material functions to establish electrical connections between adjoining layers of the interlaced materials, such as the layers depicted at 613. The electrical connections between the adjoining layers of the interlaced materials form one or more electrical VIASes within the textile structure. At 622, a multi-functional sensor 125 actuator 126 configuration is depicted. In the depicted example, a user may touch a capacitive touch sensor to initiate a response function. The response function may be an illumination response or any other type of response function previously discussed herein with reference to FIG. 1. At 623, an example of novel functional materials comprised within the weave structure is depicted. In the depicted example, an optical fiber is used within the weave structure as either the weft material or the warp material.

FIG. 6C depicts examples of aesthetic dimensionality for wearable device 120 or 220. Woven on-skin interfaces can support unique aesthetic properties not afforded by conventional printed or laminated approaches. Woven on-skin interfaces can provide a pattern design as depicted at 631; incorporate unusual materials, such as plastic bags or leaves, for expressive effect as depicted at 632; provide a variety of textures as depicted at 633; and incorporate blank space in the design as depicted at 634, which reveals the underlying skin and skin landmarks for aesthetic design.

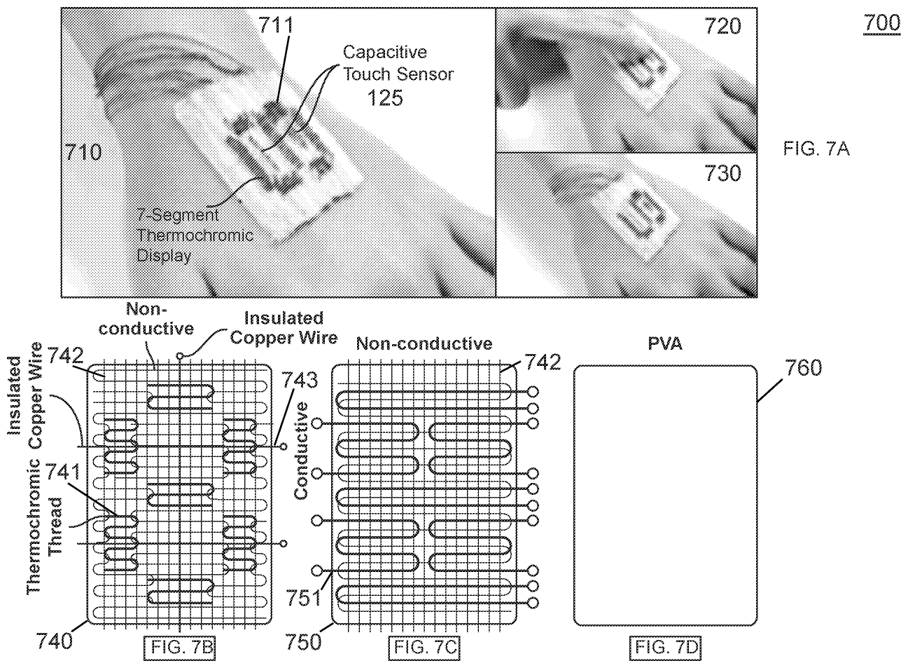

FIGS. 7A, 7B, 7C, and 7D depict an example embodiment 700 of a wearable device 120 or 220 with capacitive touch sensors and a thermochromic display, in accordance with certain examples. FIG. 7A depicts integrated input and output functions in an on-skin interface. At 710, a multi-functional interface with an output display through thermochromic yarns and an input through capacitive touch sensing is depicted. The input comprises two capacitive touch sensors 125. The output comprises a 7-segment thermochromic display 711. In an example, the thermochromic display 711 can be increased or decreased by the two capacitive touch sensors 125. The right capacitive touch sensor 125 is configured as a “+” and increases the thermochromic display 711. The left capacitive touch sensor 125 is configured as a “−” and decreases the thermochromic display 711. At 720, a user is depicted activating the “+” capacitive touch sensor.

FIG. 7B depicts a first layer 740 of the weave structure for example embodiment 700. The first layer 740 comprises thermochromic material or thread 741 for visibility, a non-conductive material 742, and an insulated copper wire 743. FIG. 7C depicts a second layer 750 of the weave structure. The second layer 750 comprises a conductive material 751 for resistive heating and non-conductive material 742. FIG. 7D depicts third layer 760 of the weave structure. The third layer 760 comprises a polyvinyl alcohol (“PVA”) film with an adhesive, referred to herein as a PVA layer.

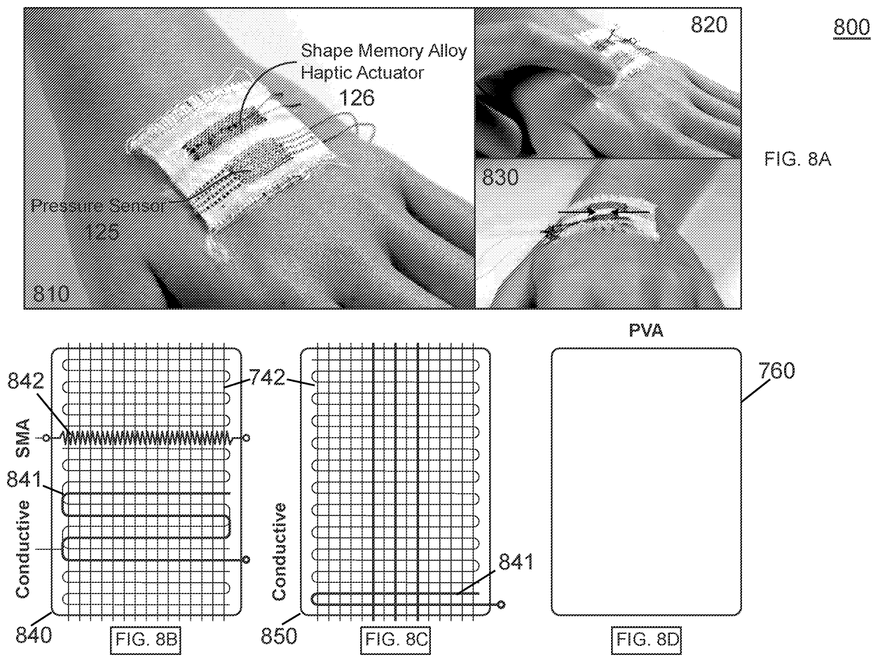

FIGS. 8A, 8B, 8C, and 8D depict an example embodiment 800 of a wearable device 120 or 220 with a pressure sensor and a haptic actuator, in accordance with certain examples. FIG. 8A depicts a multi-functional interface 810 with haptic feedback through SMA and input through pressure sensing. Example embodiment 800 comprises a pressure sensor 125 and an SMA actuator 126. In an example, example embodiment 800 is an on-skin alarm system. Example embodiment 800 combines input through pressure sensing and output through SMA haptic feedback. Due to the pressure sensing characteristics, the alarm system may register light touch and firm touch, providing two input modes, potentially with the light touch serving as a snooze button for the haptic feedback alarm. At 820, a user is depicted activating pressure sensor 125. In an example, pressure sensor 125 is based on piezoresistive sensing, which involves two electrodes separated by a piezoresistor with resistance that varies linearly with force.

FIG. 8B depicts a first layer 840 of the weave structure for example embodiment 800. The first layer 840 comprises a conductive material 841, a non-conductive material 742, and an SMA actuator 843. SMA actuator 843 is woven on the first layer as a supplementary weft in the plain weave. FIG. 8C depicts a second layer 850 of the weave structure. The second layer 850 comprises conductive material 841 and non-conductive material 742. FIG. 8D depicts a third layer 760 of the weave structure. The third layer 760 was previously described herein with reference to FIG. 7D.

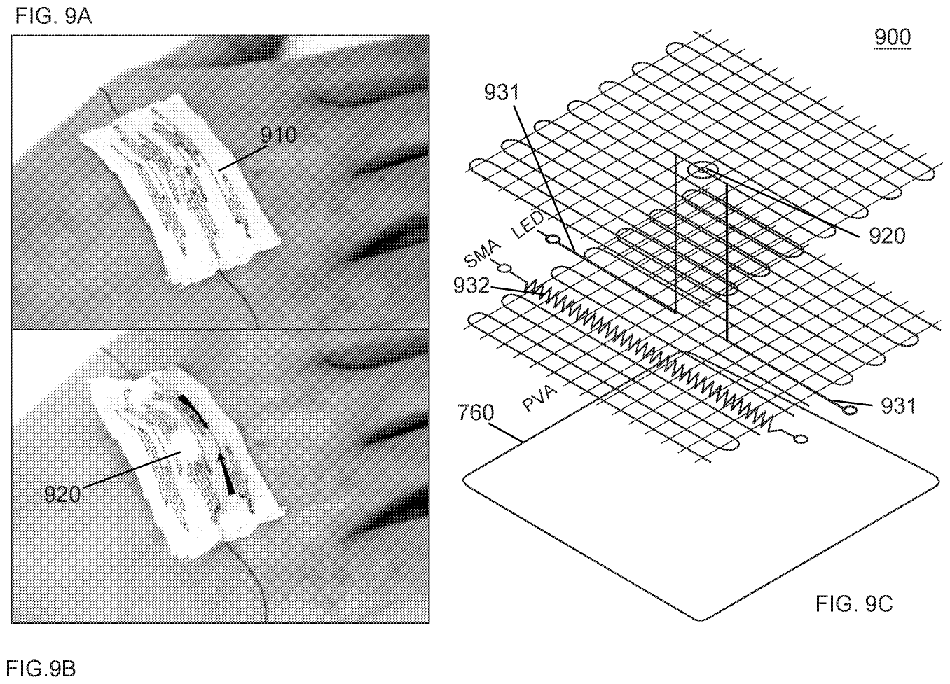

FIGS. 9A, 9B, and 9C depict an example embodiment 900 of a wearable device 120 or 220 with 3-dimensional electrical connections between layers, in accordance with certain examples. In an example, example embodiment 900 provides a two-tier output with a single voltage source. Example embodiment 900 can provide two types of notifications: the first tier (e.g., SMA haptic feedback) for non-urgent notifications and the second tier (e.g., SMA haptic feedback and LED output) for urgent notifications. FIG. 9A depicts the wearable device 910 of example embodiment 900. FIG. 9B depicts the wearable device 910 with an LED 920. FIG. 9C depicts the multi-layer weave structure 930 of the wearable device 910. The top layer comprises LED 920. A conductive material 931 is affixed to connectors on LED 920. In an example, conductive material 931 is a copper wire. Conductive material 931 is partially woven into the top layer and then inserted into a second layer of the weave structure. The second layer of the weave structure comprises an SMA spring 932. Using the VIAS in example embodiment 900, the LED 920 and SMA spring 932 can be controlled with a single voltage source. In an example, the SMA spring 932 may be activated at a voltage of 2.75 V and LED 920 may be activated at 4.0 V. Any suitable voltage values may be used to active SMA spring 932 and LED 920. A third layer of the weave structure is a PVA layer 760, previously described herein with reference to FIG. 7D.

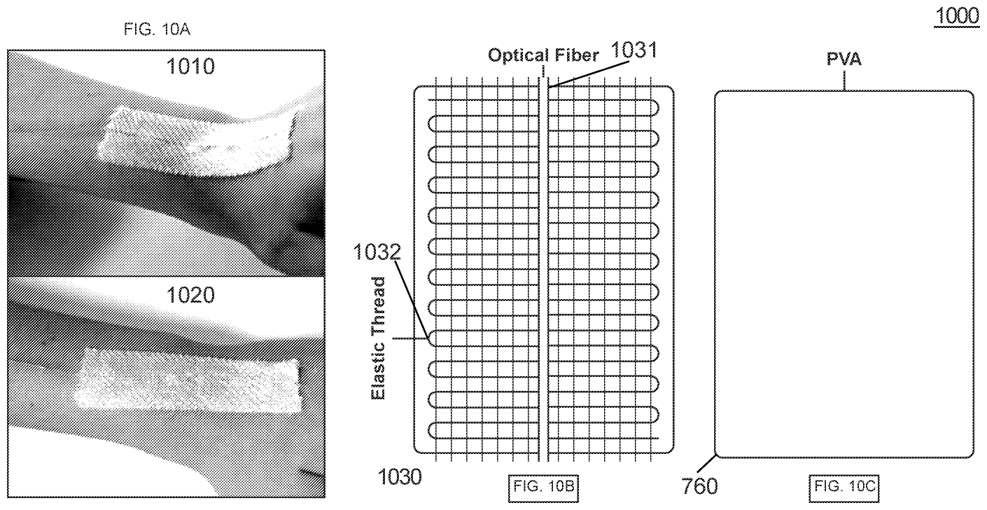

FIGS. 10A, 10B, and 10C depict an example embodiment 1000 of a wearable device 120 or 220 with functional weave material, in accordance with certain examples. FIG. 10A depicts the example embodiment 1000 affixed to a user at 1010 and 1020. FIG. 10B depicts a first layer 1030 of the weave structure The first layer 1030 comprises one or more optical fibers 1031 and an elastic thread or material 1032. In an example, optical fiber 1030 is a stretchable optical fiber. In response to the elastic material 1032 stretching or retracting, a change in light intensity is generated in optical fiber 1031. For example, a change in light intensity may occur when the wearable device is affixed to a joint and the joint bends or straightens. FIG. 10C depicts a second layer 760 of the weave structure. The second layer 760 is a PVA layer, previously described herein with reference to FIG. 7D.

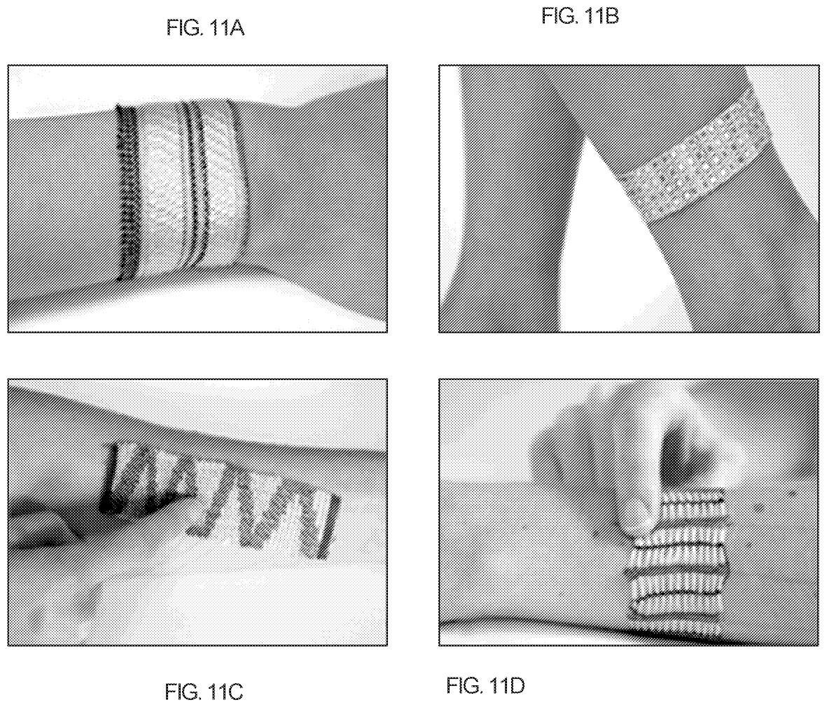

FIGS. 11A, 11B, 11C, and 11D depict example embodiments of wearable devices with aesthetic dimensionality, in accordance with certain examples. As depicted in FIG. 11A, the woven fabrication process can incorporate different materials in different weave structures, resulting in a variety of possible textures. FIG. 11A depicts an improvised twill pattern alternated with a plain weave. The twill is woven with silk, where the repetition creates a textured surface, and is interspersed with plain weave that uses a thermochromic pigmented cotton (orange to white transition at 37° C.), resulting in a subtly textured conformable skin. In an example, the thermochromic pigmented cotton transitions color at a specified temperature (i.e., from orange to white transition at 37° C.).

As depicted in FIG. 11B, the woven fabrication process allows for the fabrication of a myriad of patterns in a vast design space. Using a silk yarn with thermochromic pigment applied to it, FIG. 11B depicts a monk's belt pattern, with the pattern appearing in a specified color when heat is applied. In an example, the pattern transitions from white to blue transition at 37° C. A monk's belt has a modern aesthetic but dates to pre-Christianity and is typically used as a border treatment. A monk's belt is a blocked pattern that can create complex orthogonal geometries but only requires 4 shafts to weave.

As depicted in FIG. 11C, unconventional materials can be incorporated into a woven structure, allowing for wearable devices 120 and 220 to have a sustainable capacity by comprising organic or upcycled materials. Plastic bags can be cut into thin strips and used in the weft of a woven structure to give a second life to a single-use plastic item. Any colors or designs on the upcycled plastic can be strategically incorporated into the design of a wearable device 120 or 220. FIG. 11C depicts a balanced twill alternating the weft between strips of plastic bag and silk with supplemental insulated copper wire. The copper wire was woven continuously to create a capacitive touch trackpad for the forearm.

As depicted in FIG. 11D, blank space can be incorporated into a woven structure. Blank space can be formed with a weaving technique that gathers warp materials to expose gaps in the woven structure, revealing portions of the object underneath. In an example, blank space provides a user an opportunity to feature birthmarks, scars, freckles, vitiligo, or tattoos into the design process. FIG. 11D depicts an adapted version of a brooks bouquet lace with four warp materials gathered by a clove-hitch knot across a row. Next, six rows of plain weave and a supplemental copper wire are woven to space out the gathered warp materials before knotting an additional row of clove-hitch knots. The copper wire adds a slider capability to the wearable device 120 or 220, which can be worn around the wrist.

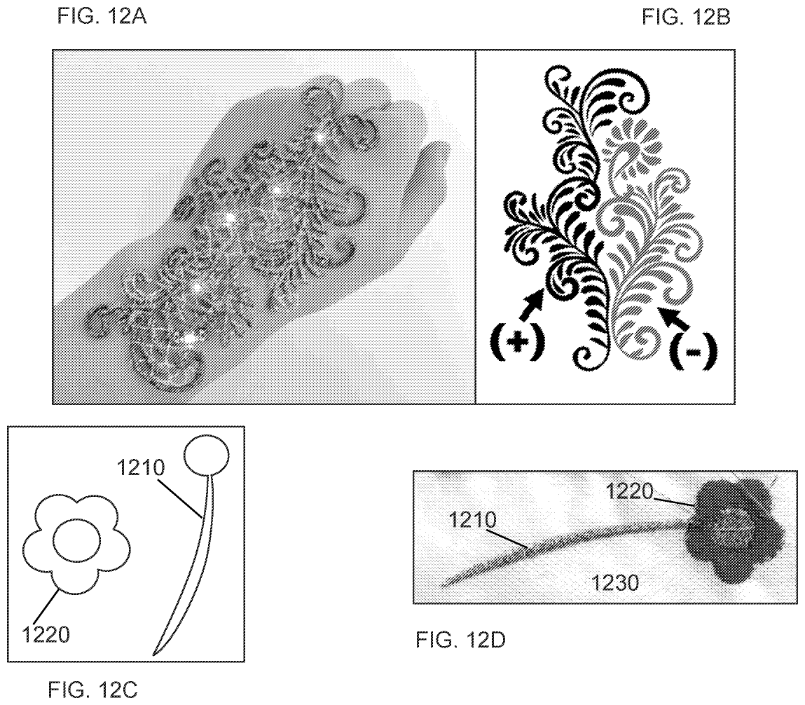

FIGS. 12A, 12B, 12C, and 12D depict example embodiments of a wearable device comprising a manufactured fabric, in accordance with certain examples. In an example, conductive materials can be added to a manufactured fabric by stitching, printing, or embroidering. Manufactured fabrics, such as lace provide benefits for wearable devices 120 and 220 including: lightweight, high ventilation, breathable, body/object surface conformable, easy fabrication, low cost, finished edges, and sustainability. FIG. 12A depicts a manufactured fabric comprising an on-skin display as an example embodiment of wearable device 120 or 220. The example embodiment of FIG. 12A may function as a textile-based on-skin PCB, which provides opportunities to enhance both functionality and aesthetics. Unlike other types of smart textile PCB, the example embodiment of FIG. 12A is not a part of another fabric structure (e.g., woven, knit, felt), and is not dependent on another supportive fabric (e.g., stitch, embroidery, silkscreen). The example embodiment of FIG. 12A has a self-formed structure with freedom in shape and porosity without loose edges. The example embodiment of FIG. 12A conforms to the 3-dimensional shaped body or object surfaces. The example embodiment of FIG. 12A increases permeability as compared to polymer-based on-skin devices and decreases the weight of the wearable device 120 and 220 and the material/production cost. The web-like motif pattern of the lace of the example embodiment of FIG. 12A allows a complex and elegant circuitry. The example embodiment of FIG. 12A depicts a wearable device 120 or 220 inspired by a bridal lace glove. The example embodiment of FIG. 12A manipulates a floral lace pattern for a soft circuit with LEDs and comprises a supportive grid where a non-conductive thread connects two conductive floral patterns, which are connected to the poles of a battery (not depicted).

FIG. 12B depicts an example embodiment as a manufactured fabric comprising two types of RFID tag antenna. The example embodiment of FIG. 12B is depicted with an NFC and an Ultra High Frequency (“UHF”) RFID tag. A chip of each tag is attached on the example embodiment of FIG. 12B antenna by a z-axis conductive tape. The NFC tag is fabricated with an antenna and a chip to respond to a portable NFC reader and an UHF RFID reader that can detect the RFID tag. The RFID tag comprises an antenna and a RFID wet inlay. The RFID tags of the example embodiment of FIG. 12B may function to identify a user as a wearable and battery-less sensor.

FIG. 12C depicts an example embodiment comprising a two-component design with a first component 1210 constructed of a conductive material and a second component 1220 constructed with a non-conductive material to be affixed to a manufactured fabric. In an example, the first component 1231 may function as a touch sensor. In an example, the two-component design is affixed to a manufactured fabric by an embroidery process. FIG. 12D depicts an example embodiment where the two-component design of FIG. 12C is affixed to a manufactured fabric 1230.

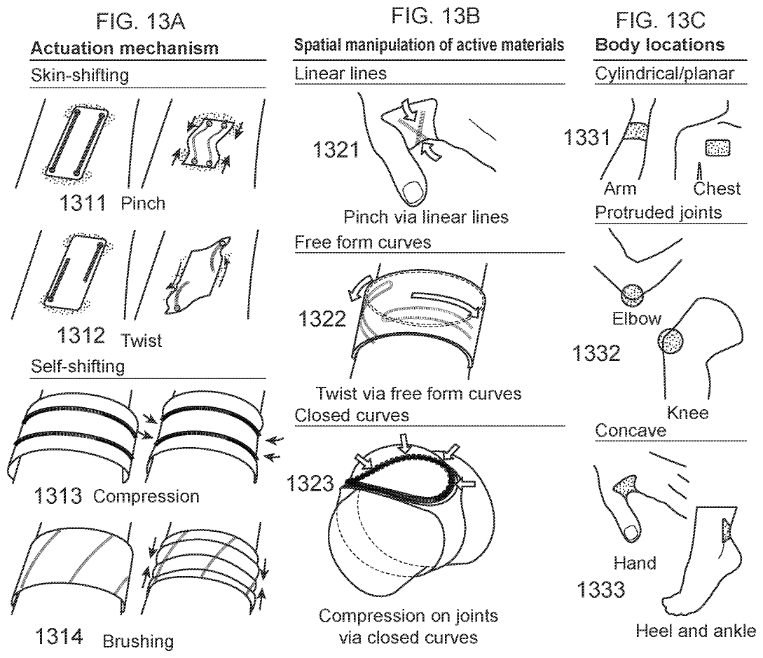

FIGS. 13A, 13B, and 13C depict example tactile actuation design factors, in accordance with certain examples. FIG. 13A depicts example actuation mechanisms and designs using SMA micro-springs as actuators 126. When current flows through the SMA micro-springs, the SMA micro-springs contract and become shorter, shifting the channels in which the SMA micro-springs are embedded. When selected areas of the substrate are attached to the skin of a user, the corresponding skin regions become shifted, and for example, can result in the pinching sensation depicted at 1311 or a twisting sensation depicted at 1312. When the wearable device 120 or 220 is attached to the skin, the SMA micro-springs may be referred to as skin-shifting actuators. The SMA micro-springs shift the contacting skin regions while the SMA micro-springs contract. The SMA micro-springs can be configured to contract in either opposing or identical directions. Actuation in identical directions results in the pulling of the skin region to a converging point, giving a pinching sensation depicted at 1311. Actuation in the opposing directions leads to wringing of the skin, resulting in a twisting sensation depicted at 1312.

Another design option is for the wearable device 120 or 220 to be close to, but not attached to the skin. When the wearable device 120 or 220 is close to, but not attached to the skin, the SMA micro-springs may be referred to as self-shifting actuators. The actuation of the SMA micro-springs can deform the interface, resulting in circumferential or lateral contraction of the interface. Circumferential contraction results in a compression sensation depicted at 1313, and lateral contraction results in a brushing sensation through the “scrunching” of the wearable device 120 or 220 depicted at 1314.

FIG. 13B depicts spatial manipulation of actuators for tactile feedback. Tactile feedback can be customized through the design of the spatial distribution of actuators 126 (i.e., SMA micro-springs) throughout the wearable device 120 or 220, which are threaded into the channels of the wearable device 120 or 220. Channels such as knitted channels afford high degrees of freedom for integrating active materials such as actuators 126. Channels can be constructed in linear lines depicted at 1321, free-form curves depicted at 1322, or closed curves depicted at 1323. Multiple channels intersect or traverse the structure independently. By having the channels constructed within the wearable device 120 or 220 textile structure, the force generated by the SMA micro-spring is transmitted to the shape of channels, displacing the channels in tandem with SMA micro-spring movement. The motion of the SMA micro-springs can produce a pinch depicted at 1321, a twist depicted at 1322, or a compression depicted at 1323.

FIG. 13C depicts example skin topographies. Tactile feedback can be customized according to an underlying skin topography or body landmark. Tactile interfaces can be designed for placement on planar (e.g., chest or back of hand) or cylindrical (e.g., forearm) body locations, as depicted at 1331. Wearable device 120 or 220 may also be designed to interface with challenging topographies such as protruded body joints depicted at 1332 and concave (hollow) body locations depicted at 1333. Protruded body joints (e.g., elbow, knees, and knuckles) can serve as “blocking barriers” that offset the force being applied against the skin. With band type wearable devices 120 or 220, the protruded landmarks can receive both tangential force from the actuation and radial force from the compression of the bands. Concave (hollow, curving inward) body locations (e.g., the purlicue, armpit, and Achilles tendon arch) need substrates that can conform to steep curvatures.

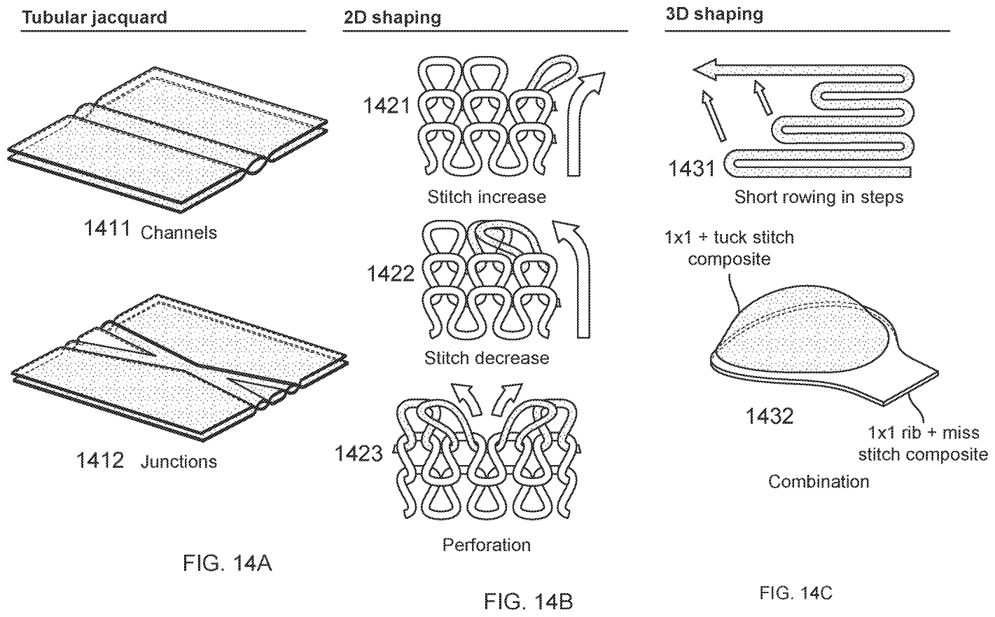

FIGS. 14A, 14B, and 14C depict knit structure design factors, in accordance with certain examples. FIG. 14A depicts knit free-form integrated channels, depicted at 1411, through tubular jacquard. Tubular jacquard is a jacquard technique where a two-color composition is knitted in a double system alternating between the front and back bed. If one material is stitched on a technical front, the other material knits on a technical back. The alternation of stitches creates tubular pockets between the two layers, which can be manipulated depth-wise (z-axis) and width length-wise (x- and y-axes) to construct a variety of channels. The tubular spaces are not limited in shape, and therefore can serve as a pocket or accommodate materials of different sizes. Variations of the technique can used to create channels and junctions, depicted at 1412, where different materials cross paths. Alternating stitches along the edges of the channels preempt the inlay material from deviating from the channels.

FIG. 14B depicts 2-dimension shaping designs for conforming wearable device 120 or 220 to challenging application locations. Transfer stitches can be used to increase, depicted at 1421, and decrease, depicted at 1422, the number of stitches in a row to change the shape of the form factor of wearable device 120 or 220. Stitch transfer can be used to gradually shape a form factor into a variety of profiles depending upon the number of stitches transferred per row as well as the frequency of the transfers. Stitch transfer is useful when generating knit substrates for concave body locations (i.e., the steep curve on the purlicue and the Achilles heel). Transfer stitches can be used to create a perforation in the form factor for incorporating an SMA micro-spring, depicted at 1423.

FIG. 14C depicts 3-dimensional shaping designs for conforming wearable device 120 or 220 to challenging application locations. Short rowing is a 3-dimensional shaping technique in which a section of needles is isolated (rather than the entire bed of needles) for knitting, depicted at 1431. When short rowing is performed in a stepped fashion, short rowing can be used to create shaped forms as well as raised 3-dimensional volumes. Combining structures is an alternative way to employ 3-dimensional shaping. Shifting from one knit structure to a second knit structure within the same form factor is an alternative approach to shaping, depicted at 1432. The differentials in abutting structures or stitches can conspicuously elevate the fabric in 3 dimensions (e.g., links structure). For use cases where the form factor covers a joint, short rowing and combining structures can build volume to accommodate the protruded body locations. Short rowing can be used to create domes encircled by tubular structures for SMA actuation. To shape larger areas into a dome, a composite of tuck and miss stitches can be used to condense and expand specific areas. The differentials in the density of the structures raise the area to form larger domes.

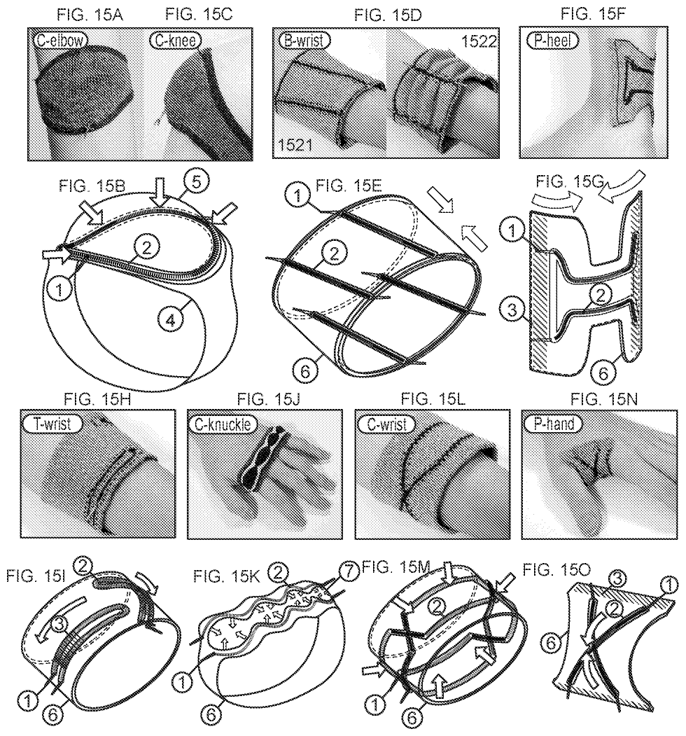

FIGS. 15A, 15B, 15C, 15D, 15E, 15F, 15G, 15H, 15I, 15J, 15K, 15L, 15M, and 15N depict use cases for a knitted form factor for wearable devices 120 or 220, in accordance with certain examples. In FIGS. 15A through 15N, numbered locations indicate the following: 1) crimp connector, 2) SMA, 3) adhesive tape, 4) 1×1 rib+miss structure, 5) tuck structure, 6) tubular jacquard, and 7) short rowing. FIG. 15A depicts a compression elbow band form factor. FIG. 15B depicts the internal components and design of the form factor of FIG. 15A. The compression elbow band form factor applies the compressing force of the band and tangential movement of a SMA micro-spring. The compression elbow band form factor configures three sub-structures: the channel, the customized elbow pad, and the strap of the band. The channel accommodates a strand of SMA micro-spring that contours the elbow. To cover the protrusion (the “dome”) of the elbow, the knit structure is constructed by adding tuck stitches, which push out the fabric to create a spherical space. A channel is constructed that encircles the elbow “dome” using tubular knitting. Building upon the tubular channel, the form factor includes a small hole that connects to the channel. The hole provides more ease of threading SMA micro-springs into the channel. A composite structure of rib and miss stitches within the strap are used to compress the width and increase the stretch. The center of the customized pad comprises tuck stitches in order to create more space for comfort. The tuck stitches push out the material forming a rounded shape to fit the elbow.

FIG. 15C depicts a compression knee band form factor. FIG. 15B depicts the internal components and design of the form factor of FIG. 15C. The compression knee band form factor applies the compressing force of the band and tangential movement of a SMA micro-spring. The compression knee band form factor configures three sub-structures: the channel, the customized knee pad, and the strap of the band. The channel accommodates a strand of SMA micro-spring that contours the patella. To cover the protrusion (the “dome” or kneecap) of the knee, the knit structure is constructed by adding tuck stitches, which push out the fabric to create a spherical space. A channel is constructed that encircles the knee “dome” using tubular knitting. Building upon the tubular channel, the form factor includes a small hole that connects to the channel. The hole provides more ease of threading SMA micro-springs into the channel. A composite structure of rib and miss stitches within the strap are used to compress the width and increase the stretch.

FIG. 15D depicts a brushing wrist band form factor. The form factor is depicted at 1521 and 1522. FIG. 15E depicts the internal components and design of the form factor of FIG. 15D. The form factor may not be attached to the skin as the form factor itself deforms, shrinking closer to the skin in a lateral movement. The form factor performs a self-shifting movement that creates a brushing sensation without applying steady pressure, which delivers light and rapid excitation to skin receptors. The self-shifting movement is enabled by the parallel positioning of four micro-springs that are evenly spaced out. For the knitted materials, materials are used with minimal tensile force, which allow for a looser stitch setting to minimize stiffness.

FIG. 15F depicts a pinching heel patch form factor. FIG. 15G depicts the internal components and design of the form factor of FIG. 15F. The heel patch may be attached to the Archilles tendon arch, which is the convex area located above the heel. Based on the topographical attributes of the Archilles tendon arch, the form factor comprises an elongated bridge and wide edges for attachment to the skin, which is enabled by active shaping. The integrated free form channels correspond to the Archilles tendon arch by contouring the selvedges, which are connected by inactive channels that carry conductive wires. For the knitted materials, materials with less tensile force are used as the form factor does not require high stretch but requires pliability.

FIG. 15H depicts a twisting wrist band form factor. FIG. 15I depicts the internal components and design of the form factor of FIG. 15H. As opposed to a pinching mechanism that pulls attached regions together to a fixed point, the twisting mechanism pulls attached regions away in opposite directions. Based on the commonly accepted two-point discrimination distance for the forearm, two discrete regions within the form factor are constructed a specified distance apart. In an example, the specified distance is at least 4 cm. The form factor moves concurrently with the activation of SMA micro-springs. Constructed with tubular jacquard, two U-shape channels contract in opposite directions toward crimp connectors, shifting the attached skin in different directions. For the knitted materials, materials that enhance stretching to generate light compression are used.

FIG. 15J depicts a compression knuckle form factor. FIG. 15K depicts the internal components and design of the form factor of FIG. 15J. The form factor is a knitted structure comprising three distinct types of sub-structures: integrated channels, an array of four knuckle pads, and the strap of the band. For effective control of compression against the knuckles, the form factor uses precise placement on the knuckles. The form factor comprises two distinct channels to contour the knuckles, where the first channel is not in contact with the second channel. The SMA micro-springs move tangentially to contract along the contour of the knuckles in concert with a moderate degree of radial compression of the band, which pushes the channels down. The shrinkage of the contoured channels under the compression of the band delivers a sensation precisely aimed at the protruded topography of the knuckles. To conform to the knuckles, the form factor comprises sculpted volumes for the four knuckle pads through short rowing. The knitted structures are then then shifted to tubular and formed two channels that flow along the contour. For the knitted materials, materials are chosen that enhance stretching. In an example, the knitted materials comprise a strand of a nylon and spandex composite yarn to provide stretch to the form factor.

FIG. 15L depicts a compression wrist form factor. FIG. 15M depicts the internal components and design of the form factor of FIG. 15L. The compression wrist form factor simulates a sense of compression. The compression wrist form factor is designed to fit along the circumference of the wrist. The form factor comprises includes two free form channels, each embedded with an SMA micro-springs. The two channels intersect due to a tubular jacquard knit structure. Tubular jacquard is a double-knit structure that produces two-color designs. The design is knit on the technical front of the form factor while the reverse of the design is knit on the technical back. Tubular jacquard serves the primary role of creating free-form tubular channels or chambers that can accommodate various inlay materials.

FIG. 15N depicts a pinching hand patch form factor. FIG. 15O depicts the internal components and design of the form factor of FIG. 15N. The pinching mechanism of the pinching hand patch form factor works by attaching the edges of the form factor to the skin of a user. The form factor comprises embedded SMA micro-springs that shift the attached regions directly. The form factor effects directional movement by moving two discrete regions of the skin at the same time. The form factor attaches to two regions of the skin: one on the dorsal and the other on the palmar aspect of the hand. To accommodate the concave structure that connects the index finger and the thumb, the form factor is designed with curved selvedges. The channels cross each other to be consistent with the shape of the form factor. The form factor mirrors an hour-glass shape, with wider edges for skin attachment, and a slimmer middle section for fitting to the area between the index finger and thumb. Intersecting SMA micro-springs present greater actuation on the edges than the middle section of the form factor.

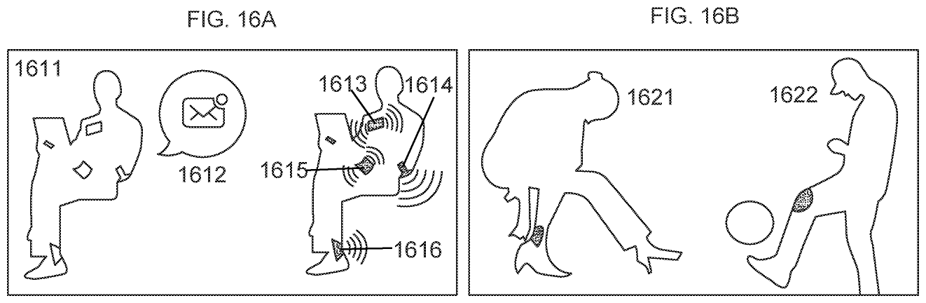

FIGS. 16A and 16B depict example use cases for wearable devices 120 or 220, in accordance with certain examples. In FIG. 16A, a user is depicted, 1611, receiving a notification, 1612. In an example, the notification may be an email, a phone call, a text message, a notification from an application, or any other type of notification. In response to the notification at 1612, wearable devices 120 or 220 apply a response function, such as a haptic response, at locations where wearable devices 120 or 220 are affixed, such as at 1613, 1614, 1615, and 1616.

In FIG. 16B, a user is depicted wearing a heel wearable device 120 or 220 at 1621. The wearable device 120 or 220 may be affixed to the user's heel or the wearable device may be incorporated into a wearable garment, such as a sock for this application. At 1622, a user is depicted wearing a knee wearable device 120 or 220. For this application, wearable device 120 or 220 may be incorporated into a wearable garment, or worn discreetly underneath a garment.

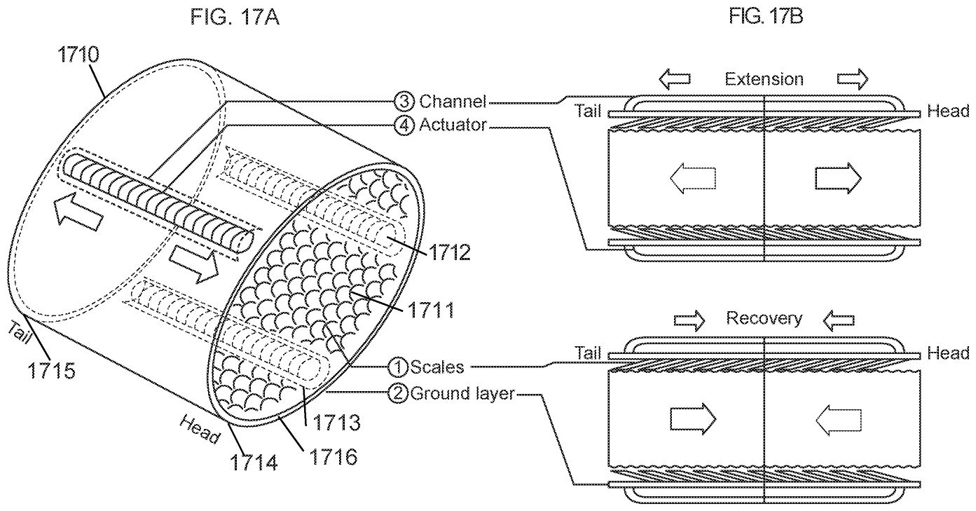

FIGS. 17A and 17B depict perspective views of a locomotion wearable device 1710, in accordance with certain examples. Locomotion wearable device 1710 comprises memory 122, microprocessor 124, and sensors 125 previously discussed herein with reference to FIG. 1 and FIG. 2. Locomotion wearable device 1710 is a soft and coordinated system configured to transverse or “crawl” cylindrical surfaces or objects. Locomotion wearable device 1710 is configured with a sleeve type, conformable form factor that exhibits anisotropic friction while in motion. Anisotropy is a property of having directional dependency. Frictional anisotropy means locomotion wearable device 1710 will produce the least resistance when being pushed towards a certain direction, for example in head direction 1714. Frictional anisotropy is a widespread mechanism behind many natural creatures: snakeskin, bur-clad plant or hairy legs of insects, and other animals. Depending on the direction of movement, angled protrusions slide smoothly or ratchet the contacting surface. To develop frictional anisotropy, locomotion wearable device 1710 comprises materials, or yarns, with conflicting characteristics of stiffness and elasticity. In an example, locomotion wearable device 1710 comprises a knitted substrate with vertical progression of knit in which a first knitted row is followed by another row to form a texture in a stacked manner. Locomotion wearable device 1710 exerts a normal force to the cylindrical surface to which locomotion wearable device 1710 is affixed that allows locomotion wearable device 1710 to transverse cylindrical surfaces in a vertical direction without slipping. In an example, locomotion wearable device 1710 is affixed to the cylindrical surface by slipping over the cylindrical surface. In an example, locomotion wearable device 1710 comprises a latching mechanism such that locomotion wearable device 1710 can be affixed to the cylindrical surface.

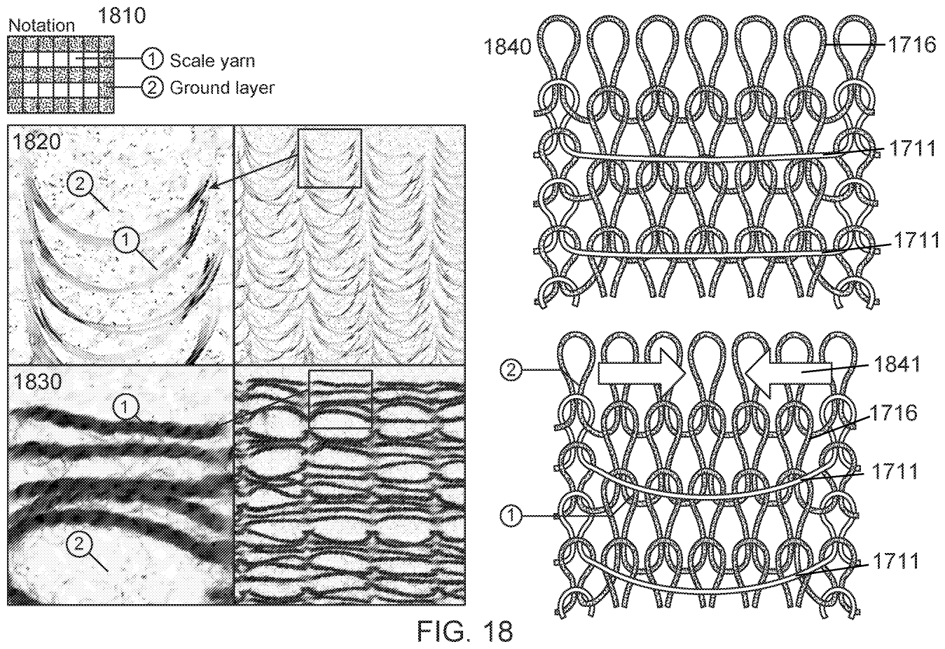

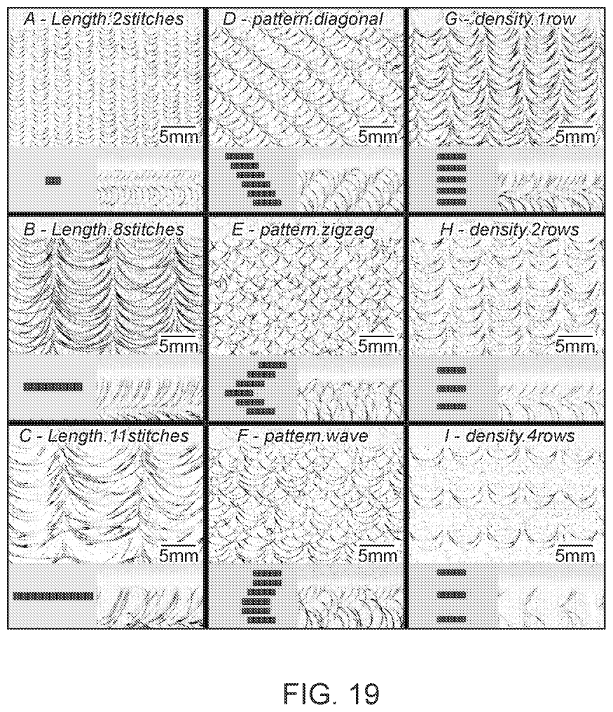

As depicted in FIG. 17A, locomotion wearable device 1710 comprises scales 1711, actuators 1712, channels 1713, a head direction 1714, a tail direction 1715, and a ground layer 1716. Scales 1711 function to provide friction to direct movement and bolster propulsion for locomotion wearable device 1710. The size, pattern, density, and roughness of scales 1711 can be varied in coordination with the elasticity of ground layer 1716. Scales 1711 are comprised of materials, or yarns, with higher stiffness and less elasticity as compared to the materials of ground layer 1716. In an example, scales 1711 are knitted row-wise, with the scale tips stacking over the succeeding rows, creating a stepped texture. The configuration of scales 1711 is discussed in greater detail herein with reference to FIGS. 18 and 19.

Locomotion wearable device 1710 comprises actuators 1712. One or more actuators 1712 are embedded within each channel 1713. In an example, actuators 1712 are fluidic actuators, such as a fluidic yarn actuator, that linearly extend to enable propulsion of locomotion wearable device 1710. In an example, actuators 1712 are pneumatic actuators that linearly extend to enable propulsion of locomotion wearable device 1710. In an example, actuators 1712 are connected to a pressure source, not depicted in FIG. 17. Actuators 1712 may be a SMA yarn actuator, a shape memory polymer yarn actuator, a carbon nano tube yarn actuator, a polymetric nanofiber, a dielectric elastomer yarn actuator, or any type of actuator 126, previously discussed herein with reference to FIG. 1 and FIG. 2. In an example, actuators 1712 are soft pneumatic actuators with pleated sheaths to supply a high thrust force. Actuators 1712 comprise inner tubing, pleated sheath, and 3-dimensional printed fittings, not depicted in FIG. 17. In an example, the pleated sheath is an expandable braided sleeve with pleats formed by compressing the braided sleeve axially while expanding the braided sleeve radially. The braided sleeve is heat treated to secure the pleats. The resulting pleated mesh contains the radial expansion of the inner tubing, thus forcing the expansion to translate axially. In an example, to expand the actuators, a compressor is used with a regulated output pressure of 42 psi. The compressor output is fed into the actuators through a 3-way pneumatic solenoid valve, not depicted. The solenoid valve is fed with 12V pulses to achieve repeated expansion and contraction of the actuators 1712. The solenoid valve is connected to a normally closed configuration. When the solenoid valve is supplied with 12V, air flows from the compressor to the actuators and expands the actuators. When the solenoid valve is supplied with 0V, the air in the actuators is exhausted through the exhaust port of the valve. A digital pressure gauge may be used to monitor the pressure in the actuators.

Locomotion wearable device 1710 comprises channels 1713. Channels 1713 can be knitted with either the material for scales 1711 or ground layer 1716. To enclose a variety of sizes of actuators 1711, channels 1713 comprise a tubular jacquard structure. The tubular jacquard structure creates pouches in various shapes and dimensions. By altering tubular jacquard, channels 1713 can accommodate differing numbers of actuators 1712 in different shapes. Channels 1713 may be constructed in conjunction with scale 1711 and ground layer 1716. In addition to actuators 1712, a variety of materials or devices may also be embedded into channels 1713 through a knitted hole, without additional efforts for integration.

Locomotion wearable device 1710 is depicted with a head direction 1714 and a tail direction 1715. Head direction 1714 and tail direction 1715 will be discussed in greater details herein with reference to FIG. 17B.

Locomotion wearable device 1710 comprises a ground layer 1716. Ground layer 1716 may also be referred to as a base layer. Ground layer 1716 is comprised of a material with elastic properties. In an example, ground layer 1716 is knitted with regular knit loops. As ground layer 1716 and scales 1711 are knitted, stress builds within ground layer 1716. When released from a knitting apparatus, the stress built up in the ground layer 1716 enables the entire structure of locomotion wearable device 1710, including scales 1711, to draw inward or shrink. Ground layer 1716 pulls scales 1711 laterally. The shrinkage is larger along the rows than columns, affecting a great amount of lateral flexing of scales 1711. An adequate amount of elasticity in ground layer 1716 and stiffness in scales 1711 is needed for balance. The balance between the elasticity in ground layer 1716 and the stiffness in scales 1711 determines the angled orientation of the scales. For example, if the scale material exhibits little stiffness, scales 1711 will have a negligible curve. When scales 1711 are straight or have negligible curve, scales 1711 will not stack onto each other and accordingly lose the stepped texture.

FIG. 17B depicts extension and recovery of locomotion wearable device 1710. During propulsion of locomotion wearable device 1710, locomotion wearable device 1710 is configured to move forward or extend in the head direction 1714 of locomotion wearable device 1710. During extension, scales 1711 on the head direction 1714 side of locomotion wearable device 1710 slide forward while scales 1711 on the tail direction 1714 side of locomotion wearable device 1710 interlock with the cylindrical surface. During recovery, scales 1711 on the tail direction 1714 side of locomotion wearable device 1710 propel toward the head direction 1714 while scales 1711 on the head direction 1714 side of locomotion wearable device 1710 anchor on the cylindrical surface.

FIG. 18 depicts a knitted structure to form a scaled substrate of a locomotion wearable device 1710, in accordance with certain examples. At 1810, a notation is depicted with a scale yarn, or scale material, at 1 and a ground layer yarn, or ground layer material, at 2. The notation indicates that five needles are skipped to form a scale 1711. At 1820, an example scale 1711 is depicted at 1 and an example ground layer 1716 is depicted at 2. In an example, scales 1711 comprise a nylon monofilament. The stiffness of the nylon monofilament induces the curvature of scales 1711 depicted at 1820. At 1830, an example scale 1711 is depicted at 1 and an example ground layer 1716 is depicted at 2. Scales 1711 are depicted with negligible curvature due to a lack of stiffness in the scale material. The scales 1711 are essentially straight, without a stepped texture. At 1840, scales 1711 and ground layer 1716 are depicted as a knitted substrate with five needles skipped. At 1841, arrows indicate the lateral pull or shrinkage as the knitted substrate is removed from a knitting apparatus, with scales 1711 depicting a curvature as compared to scales 1711 depicted at 1840.

FIG. 19 depicts example geometric parameters of scales 1711, in accordance with certain examples. To achieve frictional anisotrophy, the inner surface of locomotion wearable device 1710 is shaped with an array of angled protuberances. A protuberance is an obstacle on a surface, sometimes referred as bumps or hairs. The scales 1711 of locomotion wearable device 1710 can be seen as an array of protuberances. The protuberances have angles because the scale 1711 tips stack over the scales 1711 on succeeding rows. The size of a scale 1711 is determined by the number of needles skipped between two ends of a scale 1711. When a material, or yarn, skips a needle, the material runs across the back of the fabric instead of forming a knit loop. The free strand of the yarn forms a downward arch once the ground layer 1716 is released from the needle bed. In an example, the scale 1711 lengths may be 2, 5, or 11 stitches, as depicted in FIG. 19 at A, B, and C. Any suitable number of stitches may be used to comprise the length of scales 1711. However, a 2-stitch is the smallest length in order for scales 1711 to curve.

The pattern of scales 1711 influences the behavior of locomotion wearable device 1710. In the knitting process, scales 1711 are knitted row by row. Knitting row by row controls how scales 1711 are stacked and which part of a scale 1711 is weighed down. When scales 1711 are stacked, the tendency to roll back diminishes as the adjacent scales 1711 are exerting pressure. For example, in the zigzag pattern depicted in FIG. 19 at E, each scale 1711 is stacked under the halves of two scales 1711 on the succeeding row, yielding a balanced configuration. Scales 1711 in the diagonal pattern depicted in FIG. 19 at D leave the right end of a scale 1711 uncompressed by adjacent scales 1711. Scales 1711 in the wave pattern depicted in FIG. 19 at F comprise a less controlled array from a side view. The patterns depicted at D, E, and F have a better rollback resistance as compared with the column pattern depicted at A, B, and C, because the column pattern has fewer overlaps among the scales 1711.

Density is defined as the distance between two rows with scales 1711. For example, a density of 1 row indicates the scales are knitted every other row. FIG. 19 at G, H, and I, depicts densities of 1, 2, and 4 rows, respectively. A low density yields low anisotropic friction because it exposes more ground layer 1716 materials, or yarns, and the friction from the ground layer 1716 is essentially uniform across all directions.

While the geometrical parameters affect the global behavior of locomotion wearable device 1710, the yarn material determines the characteristics of scales 1711. In an example, scales 1711 may be knitted with a nylon monofilament, 38 AWG copper wire, or silver-plated multi-filament material. Any material of suitable stiffness may be used for scales 1711. The surface and cross-section of a material influences the overall roughness of scales 1711, which in turn impacts the friction. Single filament materials such as nylon monofilaments and metal wires exhibit smoother surfaces with a solid cross-section, often in the shape of a circle. Alternately, multi-material yarns such as silver-plated multi-filament comprise a core yarn and a wrapper, resulting in a non-uniform cross-section. The bristly surface of multi-material yarns, which are akin to the metal plated yarns, can also be attributed to the incoherent yarn composition. The curvature of scales 1711 is closely tied to the capability of the material to store tension during and after the knitting process. The scale curvature is determined by two primary facets: material stiffness and elasticity.

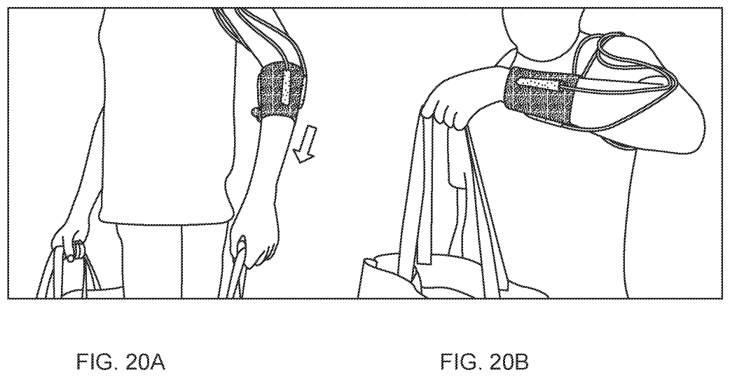

FIGS. 20A and 20B depict an example use case of a locomotion wearable device 1710, in accordance with certain examples. Based on the design of scales 1711, locomotion wearable device 1710 is capable of motion relative to a variety of surface materials including synthetic materials such as polyurethane laminated fabric (“PUL”), silicone rubber, and neoprene, each of which share the properties of human skin. In an example, with the soft and knitted form factor of locomotion wearable device 1710, locomotion wearable device 1710 resembles a garment or clothing, making locomotion wearable device 1710 an appropriate form factor for on-body locomotion. In addition to the form factor, channels 1713 may accommodate a wide range of actuators 1712. Channels 1713 may be altered to create a pocket for input sensors, such as sensors 125, and output feedback modules, such as actuators 126. In the example use case depicted in FIG. 20, locomotion wearable device 1710 can change locomotion wearable device 1710's location for voice input. When an interface of locomotion wearable device 1710 receives an incoming call while both of a user's hands are busy as depicted in FIG. 20A, locomotion wearable device 1710 crawls down to the lower arm of the user for easier voice input, depicted in FIG. 20B. The channels 1713 may be modified to embed an accelerometer for detecting the motion of both hands, which in turn triggers locomotion. A miniaturized portable air compressor may be used to pressurize the actuators 1712. In an example, the air compressor is connected directly to the actuators 1712 and is programmed to periodically inflate actuators 1712 to a predefined pressure, followed by subsequent exhaustion of the air to produce the desired locomotion. In an alternate example, locomotion wearable device 1710 may be used for health and rehabilitation applications. Channels 1713 may be designed to enfold a wide range of actuators, such as actuators 126, and materials such as SMA to provide functionality such as compression, vibration, stiffness, pinching, brushing, or twisting. Channels 1713 may be configured laterally as well as longitudinally to enclose SMA along the circumference of arm. Locomotion wearable device 1710 may climb up and down the arm to convey compression, or other functionality, on varying locations.

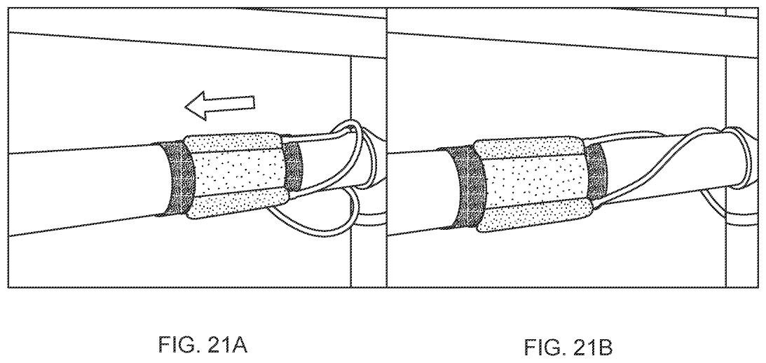

FIGS. 21A and 21B depict an industrial application use case of a locomotion wearable device 1710, in accordance with certain examples. The programmability of ground layer 1716 and scales 1711 affords the use of diverse and unconventional materials for knitting. By knitting in a strand of water-soluble polyvinyl alcohol (PVA) thread to ground layer 1716, locomotion wearable device 1710 can function as an interface that passively reacts to moisture in the environment, such as a pipe-leakage monitoring and protection sleeve. Locomotion wearable device 1710 can travel along the length of a pipe and reach inaccessible regions, as depicted in FIG. 21A. When locomotion wearable device 1710 is exposed to water leaks, the PVA thread dissolves and solidifies locomotion wearable device 1710 to stop the leak. By nature of PVA thread, the dissolution induces considerable shrinkage of the substrate, resulting in a tight grip of locomotion wearable device 1710 around the leak location, as depicted in FIG. 21B. As locomotion wearable device 1710 dries, locomotion wearable device 1710 remains solid. The resulting interface between locomotion wearable device 1710 and the pipe could serve as a temporary fix for a water leak without requiring external sensing systems.

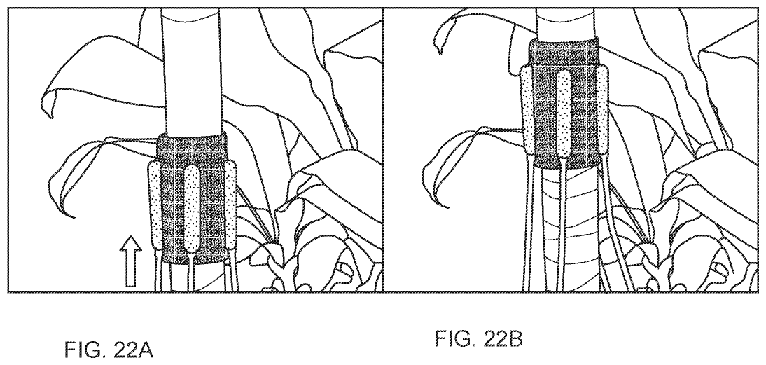

FIGS. 22A and 22B depict an agricultural application use case of a locomotion wearable device 1710, in accordance with certain examples. Locomotion wearable device 1710 can be affixed to surfaces with distinct texture. In an example, bark-clad tree branches offer a unique application for locomotion wearable device 1710. By crawling up vertical trunks and angled branches as depicted in FIG. 22A, locomotion wearable device 1710 can serve as a soft, relocatable tree guard, as depicted in FIG. 22B. Locomotion wearable device 1710 provides a simplistic solution to common issues with existing plastic wraps, which leave an abrasion and can result in bark disease due to excessive moisture captured within the plastic wrap. The porous structure of knits allow air to flow freely through locomotion wearable device 1710, while maneuvering with minimal damage to a tree. Alternatively, ground layer 1716 could be knitted with insect repellent yarns to protect young trees from insect pests which can be harmful for the tree. If equipped with a portable pesticide spray, locomotion wearable device 1710 could also serve as a minimally intrusive pesticide dispenser that does not spread unneeded chemicals to other trees.

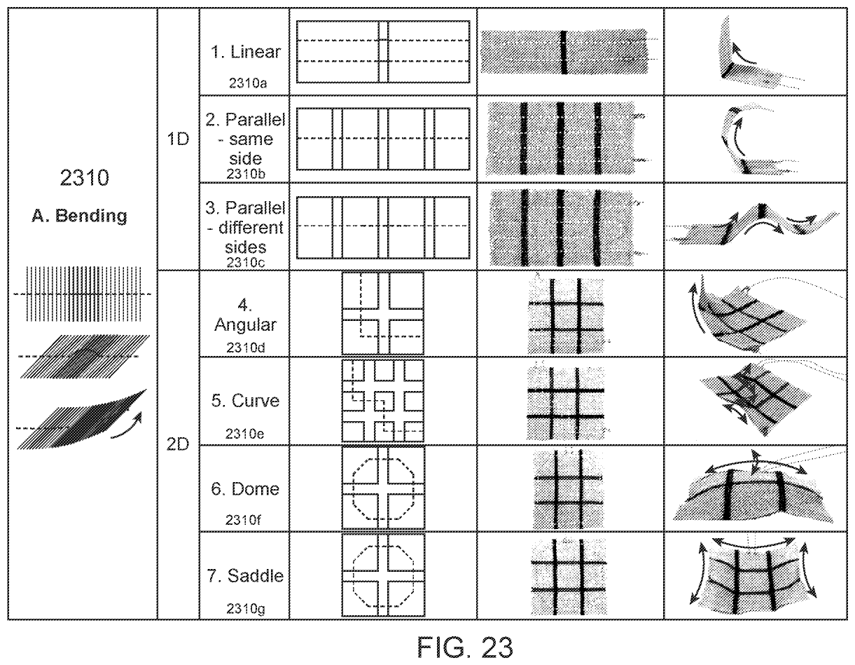

FIG. 23 depicts a bendable patch wearable device 2310, in accordance with certain examples. A patch wearable device, such as bendable patch wearable device 2310, expandable patch wearable device 2410, and shrinkable patch wearable device 2510, is a deformable interface devised as a woven patch that enables diverse movement-based interactions adaptive to garments or on-skin wearing. The patch wearable device is a detachable and relocatable actuation unit that can be sewn or attached to clothing or skin at various locations. The patch wearable device integrates actuators at a structural level and varies the texture and stiffness of the woven substrate. The woven substrate is embedded with SMA actuators. The patch wearable device may be woven with unique structural and yarn material combinations, which yields a versatile woven substrate tunable for different actuation mechanisms. Taking advantage of the structural and textural flexibility of weaving, the patch wearable device enables slim integration while preserving expressive weave aesthetics.

The patch wearable device comprises two main components: (1) SMA actuators, and (2) woven fabric substrates. SMA actuators may be SMA wire for shape memory, SMA wire for contraction, or an SMA spring. The SMA wire can be used for contraction, providing a stable and accurate length shrinkage via heating. The SMA wire for shape memory is malleable when cold but can return to a trained shape when heated. In an example, the SMA spring has a dense helix structure. The SMA spring can be stretched to more than 200% of the original length and contracts significantly when actuated. The warp and weft yarns for the patch wearable device were chosen to enhance the movement of the fabric patch upon actuation. Certain areas of the patch wearable device may bend easily while other areas may be stiff to ensure a hinge-like movement upon actuation. A machine-spun unbleached linen yarn is stiff, rough and has low elasticity. A silk yarn has a smooth surface with near-constant diameter, high tensile strength, stretches from 15 to 20 percent, and is mechanically compressible. By combining of linen and silk yarns in the warp and weft directions, localized physical properties of the patch wearable device can be manipulated. In an example, synthetic fibers can be used to reduce the production cost of the patch wearable device.

In addition to material variations, weave structures for the base fabric substrate of the patch wearable device and fabrication techniques for SMA integration may accentuate stiffness and pliability of specific areas of the patch wearable device. Weave patterns may be alternated between plain weave and twill weave. Tapestry may be used to create regions with different weave patterns. To create a plain weave, the weft yarn is alternated over and under each warp yarn to create a checkerboard-like pattern. In a twill weave, the weft yarn passes over one warp yarn followed by under two warp yarns to create diagonal ribs. In the plain weave, simple overlapping of yarns ensures that the weave angle remains stable at 90 degrees despite repeated bending, thereby, preventing distortions in the weave pattern. A plain weave may be incorporated at locations that would undergo repeated folding. In a twill weave, the distance between two adjacent yarns is smaller, which in turn prevents the fabric from compressing into small folds. A twill weave may be incorporated at locations required to be stiff.

In patch wearable devices integrating SMA springs, a double weave pattern may be used to incorporate the SMA springs between layers. To create the double weave, two layers of plain weave are interconnected on both sides. Five interlacing arrangements may be used to integrate an SMA actuator within the patch wearable device's weaving process. First, the SMA actuator can be integrated as a floating warp/weft to perform an unrestricted deformation and replicate a hinge-like behavior. Second, the SMA actuator can be interlaced within the weave as a supplementary warp or supplementary weft to ensure that the SMA actuator is clamped in place. Third, in the case of multi-layer fabrics, the VIAS was adopted from circuit boards to weaving planes. The SMA wire-form actuators serve as VIAS for linking a multi-layer cloth for a specific deformation design. While integrating the SMA actuator, the SMA actuator can be incorporated at angles other than right angles aligned with warp and weft through hand-manipulation as adopted in lace weaving. Woven fabric is unique in woven fabric is tunable stiffness, which is endowed by both the fiber material and the adopted weave pattern.

For bendable patch wearable device 2310, bendable patch wearable device 2310 may bend in a 1-dimensional linear bend depicted in the examples at row 2310a. Bendable patch wearable device 2310 may bend in a 1-dimensional parallel same side bend depicted in the examples at row 2310b. Bendable patch wearable device 2310 may bend in a 1-dimensional parallel different side bend depicted in the examples at row 2310c. Bendable patch wearable device 2310 may bend in a 2-dimensional angular bend depicted in the examples at row 2310d. Bendable patch wearable device 2310 may bend in a 2-dimensional curve bend depicted in the examples at row 2310e. Bendable patch wearable device 2310 may bend in a 2-dimensional dome bend depicted in the examples at row 2310f. Bendable patch wearable device 2310 may bend in a 2-dimensional saddle bend depicted in the examples at row 2310g.

In an example, the bending mechanism for bendable patch wearable device 2310 is translated to woven interfaces, with the basic actuation unit of bending comprising two types of woven regions. An SMA wire may be used for contraction in this form factor. In an example, the SMA wire is rated with a standard drive voltage of 20.7 V/m and a standard drive current of 340 mA, which would produce 150 gram force (“gf”) and 4% kinetic strain. Any suitable drive voltage and drive current may be used. In an example, a stiffer fabric is woven on the two sides to constrain deformation. In the continuing example, the SMA wire is anchored as a supplementary weft between tensioned warps. The central region is softer but resistant to wrinkles and shrinking. The corresponding section of SMA wire in the center floats either above or below the softer region. Since the stiffer regions on the sides restrain the SMA wire, shrinkage would concentrate at the flexible region in the middle, which pulls the softer part of the fabric on both ends like drawing a bow. The bendable patch wearable device 2310 would then be bent in a direction curving toward the SMA wire.

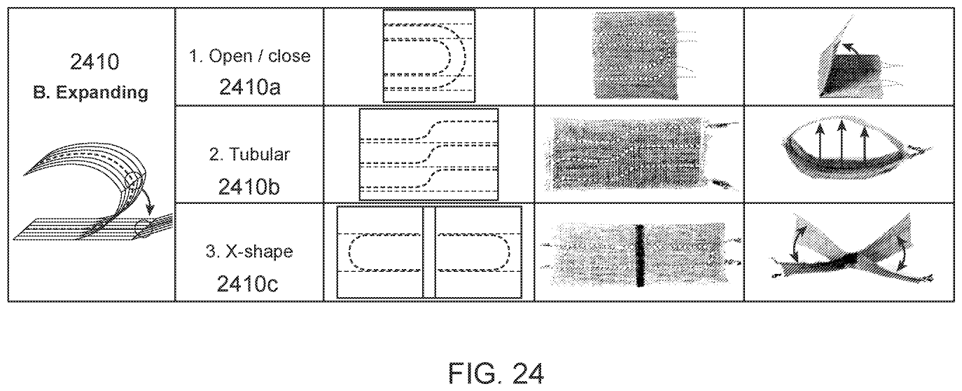

FIG. 24 depicts an expandable patch wearable device 2410, in accordance with certain examples. Expandable patch wearable device 2410 may expand in an open/close fashion as depicted in the examples at row 2410a. Expandable patch wearable device 2410 may expand in a tubular fashion as depicted in the examples at row 2410b. Expandable patch wearable device 2410 may expand in an X-shape as depicted in the examples at row 2410c.

The shape memory effect of the SMA wire can be used to expand expandable patch wearable device 2410 from a flat 2-dimensional shape to a 3-dimensional structure. In an example, a double cloth weaving technique may be used to create the expandable structure of expandable patch wearable device 2410. The double cloth weaving technique separates the weaving plane into upper and lower layers, where the two planes can be woven fully in parallel or interact with each other through selvages or interlacing weft yarns. The basic actuation unit of expanding is defined as a bent joint of SMA actuators connecting the two layers of a double cloth patch through a VIAS interlacing arrangement. Since the default trained shape of the SMA wire is a straight line, the SMA wire would recover from a bent status when actuated, which expands and opens the folded double cloth structure, as depicted at row 2410a.

In an example, a Nickel Titanium (“NiTi”) wire may be used as the SMA wire for shape memory. A variety of warp/weft materials may be used to weave the double cloth expandable patch wearable device 2410. In an example, if the top and bottom layers of expandable patch wearable device 2410 need to be connected, a silk warp material in the connecting margin will allow expandable patch wearable device 2410 to be more flexible. A representative design of the expanding patch is a tubular shape, where the top and bottom layers are connected on both sides. As shown at row 2410b, the SMA joints are distributed evenly along the two edges of the tube.

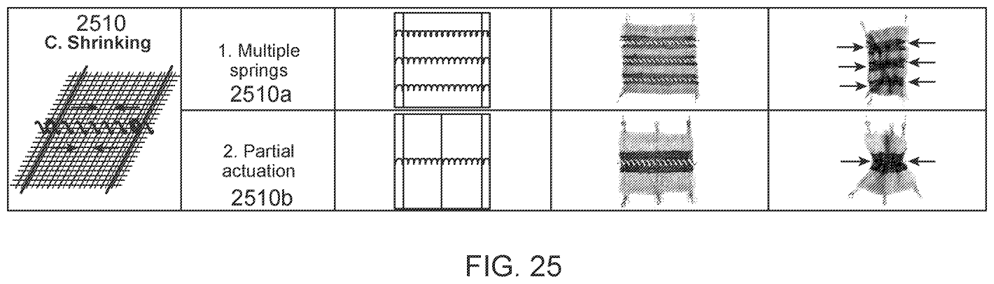

FIG. 25 depicts a shrinkable patch wearable device 2510, in accordance with certain examples. Shrinkable patch wearable device 2510 may comprise multiple SMA springs to shrink the entirety of the form factor of shrinkable patch wearable device 2510 as depicted in the examples at row 2510a. Shrinkable patch wearable device 2510 may comprise a single SMA spring for partial actuation/shrinkage of the form factor of shrinkable patch wearable device 2510 as depicted in the examples at row 2510b.

In contrast to the bending and expanding mechanisms that deform the patch wearable device along a line, the shrinking mechanism creates a much more prominent shrinkage across the entire form factor of shrinkable patch wearable device 2510 by leveraging SMA springs. The basic actuation unit of shrinking involves looped copper wires for electrical connection and an SMA spring integrated into the weft in a plain weave.

In an example, SMA springs can generate a strong contraction force. Softer and more stretchable materials for both weft and warp materials are used in shrinkable patch wearable device. In an example, the SMA spring is first stretched before integration into the weave of shrinkable patch wearable device 2510. The SMA spring may be stretched to 7 coils/inch, or any other suitable length. The SMA spring can stand 3.4A current to achieve a 2-second actuation. The weaving starts with a loose plain weave structure suitable for integrating the SMA spring. Each round of the SMA springs clutch the weft and warp materials, and the structure may be tightened after integration of the SMA springs by increasing the beating intensity of consecutive wefts. In an example, the fabrication process comprises three steps: (1) perform a loose plain weave until arriving at the position for SMA spring integration; (2) create loops with a copper warp; and (3) install the SMA springs and tighten the plain weave.

### Other Examples

FIG. 26 depicts a computing machine 2600 and a module 2650 in accordance with certain examples. The computing machine 2600 may correspond to any of the various computers, servers, mobile devices, embedded systems, or computing systems presented herein. The module 2650 may comprise one or more hardware or software elements configured to facilitate the computing machine 2600 in performing the various methods and processing functions presented herein. The computing machine 2600 may include various internal or attached components such as a processor 2610, system bus 2620, system memory 2630, storage media 2640, input/output interface 2660, and a network interface 2670 for communicating with a network 2680.

The computing machine 2600 may be implemented as a conventional computer system, an embedded controller, a laptop, a server, a mobile device, a smartphone, a set-top box, a kiosk, a router or other network node, a vehicular information system, one or more processors associated with a television, a customized machine, any other hardware platform, or any combination or multiplicity thereof. The computing machine 2600 may be a distributed system configured to function using multiple computing machines interconnected via a data network or bus system.

The processor 2610 may be configured to execute code or instructions to perform the operations and functionality described herein, manage request flow and address mappings, and to perform calculations and generate commands. The processor 2610 may be configured to monitor and control the operation of the components in the computing machine 2600. The processor 2610 may be a general purpose processor, a processor core, a multiprocessor, a reconfigurable processor, a microcontroller, a digital signal processor (“DSP”), an application specific integrated circuit (“ASIC”), a graphics processing unit (“GPU”), a field programmable gate array (“FPGA”), a programmable logic device (“PLD”), a controller, a state machine, gated logic, discrete hardware components, any other processing unit, or any combination or multiplicity thereof. The processor 2610 may be a single processing unit, multiple processing units, a single processing core, multiple processing cores, special purpose processing cores, co-processors, or any combination thereof. The processor 2610 along with other components of the computing machine 2600 may be a virtualized computing machine executing within one or more other computing machines.

The system memory 2630 may include non-volatile memories such as read-only memory (“ROM”), programmable read-only memory (“PROM”), erasable programmable read-only memory (“EPROM”), flash memory, or any other device capable of storing program instructions or data with or without applied power. The system memory 2630 may also include volatile memories such as random access memory (“RAM”), static random access memory (“SRAM”), dynamic random access memory (“DRAM”), and synchronous dynamic random access memory (“SDRAM”). Other types of RAM also may be used to implement the system memory 2630. The system memory 2630 may be implemented using a single memory module or multiple memory modules. While the system memory 2630 is depicted as being part of the computing machine 2600, one skilled in the art will recognize that the system memory 2630 may be separate from the computing machine 2600 without departing from the scope of the subject technology. It should also be appreciated that the system memory 2630 may include, or operate in conjunction with, a non-volatile storage device such as the storage media 2640.

The storage media 2640 may include a hard disk, a floppy disk, a compact disc read only memory (“CD-ROM”), a digital versatile disc (“DVD”), a Blu-ray disc, a magnetic tape, a flash memory, other non-volatile memory device, a solid state drive (“SSD”), any magnetic storage device, any optical storage device, any electrical storage device, any semiconductor storage device, any physical-based storage device, any other data storage device, or any combination or multiplicity thereof. The storage media 2640 may store one or more operating systems, application programs and program modules such as module 2650, data, or any other information. The storage media 2640 may be part of, or connected to, the computing machine 2600. The storage media 2640 may also be part of one or more other computing machines that are in communication with the computing machine 2600 such as servers, database servers, cloud storage, network attached storage, and so forth.

The module 2650 may comprise one or more hardware or software elements configured to facilitate the computing machine 2600 with performing the various methods and processing functions presented herein. The module 2650 may include one or more sequences of instructions stored as software or firmware in association with the system memory 2630, the storage media 2640, or both. The storage media 2640 may therefore represent machine or computer readable media on which instructions or code may be stored for execution by the processor 2610. Machine or computer readable media may generally refer to any medium or media used to provide instructions to the processor 2610. Such machine or computer readable media associated with the module 2650 may comprise a computer software product. It should be appreciated that a computer software product comprising the module 2650 may also be associated with one or more processes or methods for delivering the module 2650 to the computing machine 2600 via the network 2680, any signal-bearing medium, or any other communication or delivery technology. The module 2650 may also comprise hardware circuits or information for configuring hardware circuits such as microcode or configuration information for an FPGA or other PLD.

The input/output (“I/O”) interface 2660 may be configured to couple to one or more external devices, to receive data from the one or more external devices, and to send data to the one or more external devices. Such external devices along with the various internal devices may also be known as peripheral devices. The I/O interface 2660 may include both electrical and physical connections for operably coupling the various peripheral devices to the computing machine 2600 or the processor 2610. The I/O interface 2660 may be configured to communicate data, addresses, and control signals between the peripheral devices, the computing machine 2600, or the processor 2610. The I/O interface 2660 may be configured to implement any standard interface, such as small computer system interface (“SCSI”), serial-attached SCSI (“SAS”), fiber channel, peripheral component interconnect (“PCI”), PCI express (PCIe), serial bus, parallel bus, advanced technology attached (“ATA”), serial ATA (“SATA”), universal serial bus (“USB”), Thunderbolt, FireWire, various video buses, and the like. The I/O interface 2660 may be configured to implement only one interface or bus technology. Alternatively, the I/O interface 2660 may be configured to implement multiple interfaces or bus technologies. The I/O interface 2660 may be configured as part of, all of, or to operate in conjunction with, the system bus 2620. The I/O interface 2660 may include one or more buffers for buffering transmissions between one or more external devices, internal devices, the computing machine 2600, or the processor 2610.

The I/O interface 2660 may couple the computing machine 2600 to various input devices including mice, touch-screens, scanners, electronic digitizers, sensors, receivers, touchpads, trackballs, cameras, microphones, keyboards, any other pointing devices, or any combinations thereof. The I/O interface 2660 may couple the computing machine 2600 to various output devices including video displays, speakers, printers, projectors, tactile feedback devices, automation control, robotic components, actuators, motors, fans, solenoids, valves, pumps, transmitters, signal emitters, lights, and so forth.

The computing machine 2600 may operate in a networked environment using logical connections through the network interface 2670 to one or more other systems or computing machines across the network 2680. The network 2680 may include WANs, LANS, intranets, the Internet, wireless access networks, wired networks, mobile networks, telephone networks, optical networks, or combinations thereof. The network 2680 may be packet switched, circuit switched, of any topology, and may use any communication protocol. Communication links within the network 2680 may involve various digital or an analog communication media such as fiber optic cables, free-space optics, waveguides, electrical conductors, wireless links, antennas, radio-frequency communications, and so forth.

The processor 2610 may be connected to the other elements of the computing machine 2600 or the various peripherals discussed herein through the system bus 2620. It should be appreciated that the system bus 2620 may be within the processor 2610, outside the processor 2610, or both. Any of the processor 2610, the other elements of the computing machine 2600, or the various peripherals discussed herein may be integrated into a single device such as a system on chip (“SOC”), system on package (“SOP”), or ASIC device.

Examples may comprise a computer program that embodies the functions described and illustrated herein, wherein the computer program is implemented in a computer system that comprises instructions stored in a machine-readable medium and a processor that executes the instructions. However, it should be apparent that there could be many different ways of implementing examples in computer programming, and the examples should not be construed as limited to any one set of computer program instructions. Further, a skilled programmer would be able to write such a computer program to implement an example of the disclosed examples based on the appended flow charts and associated description in the application text. Therefore, disclosure of a particular set of program code instructions is not considered necessary for an adequate understanding of how to make and use examples. Further, those skilled in the art will appreciate that one or more aspects of examples described herein may be performed by hardware, software, or a combination thereof, as may be embodied in one or more computing systems. Moreover, any reference to an act being performed by a computer should not be construed as being performed by a single computer as more than one computer may perform the act.

The examples described herein can be used with computer hardware and software that perform the methods and processing functions described herein. The systems, methods, and procedures described herein can be embodied in a programmable computer, computer-executable software, or digital circuitry. The software can be stored on computer-readable media. Computer-readable media can include a floppy disk, RAM, ROM, hard disk, removable media, flash memory, memory stick, optical media, magneto-optical media, CD-ROM, etc. Digital circuitry can include integrated circuits, gate arrays, building block logic, field programmable gate arrays (“FPGA”), etc.

The systems, methods, and acts described in the examples presented previously are illustrative, and, alternatively, certain acts can be performed in a different order, in parallel with one another, omitted entirely, and/or combined between different examples, and/or certain additional acts can be performed, without departing from the scope and spirit of various examples. Accordingly, such alternative examples are included in the scope of the following claims, which are to be accorded the broadest interpretation so as to encompass such alternate examples.

Although specific examples have been described above in detail, the description is merely for purposes of illustration. It should be appreciated, therefore, that many aspects described above are not intended as essential elements unless explicitly stated otherwise. Modifications of, and equivalent components or acts corresponding to, the disclosed aspects of the examples, in addition to those described above, can be made by a person of ordinary skill in the art, having the benefit of the present disclosure, without departing from the spirit and scope of examples defined in the following claims, the scope of which is to be accorded the broadest interpretation so as to encompass such modifications and equivalent structures.

Various embodiments are described herein. It should be noted that the specific embodiments are not intended as an exhaustive description or as a limitation to the broader aspects discussed herein. One aspect described in conjunction with a particular embodiment is not necessarily limited to that embodiment and can be practiced with any other embodiment(s). Reference throughout this specification to “one embodiment,” “an embodiment,” “an example embodiment,” or other similar language means that a particular feature, structure, or characteristic described in connection with the embodiment is included in at least one embodiment of the invention described herein. Thus, appearances of the phrases “in one embodiment,” “in an embodiment,” “an example embodiment,” or other similar language in various places throughout this specification are not necessarily all referring to the same embodiment. Furthermore, the particular features, structures, or characteristics may be combined in any suitable manner in one or more embodiments, as would be apparent to a person having ordinary skill in the art and the benefit of this disclosure. Furthermore, while some embodiments described herein include some, but not other, features included in other embodiments, combinations of features of different embodiments are meant to be within the scope of the invention. For example, in the appended claims, any of the claimed embodiments can be used in any combination.

Example 1 is a wearable system, comprising a textile structure configured to be affixed to a location on a user, the textile structure comprising: a functional device embedded within the textile structure and enabled to provide a response function, a sensor embedded within the textile structure, and a conductor embedded within the textile structure connecting the functional device and the sensor; and a circuit configured to receive an input from the sensor and to output a signal to the functional device to initiate the response function.

Example 2 includes the subject matter of Example 1, the textile structure further comprising an adhesive layer configured to affix the textile structure to the location on the user.

Example 3 includes the subject matter of Examples 1 or 2, wherein the adhesive layer comprises a polyvinyl alcohol adhesive.

Example 4 includes the subject matter of Example 1, the textile structure further comprising a processor coupled to the circuit, the processor configured to: receive the input from the sensor; and output the signal to the functional device to initiate the response function.

Example 5 includes the subject matter of any of Examples 1-4, the textile structure further comprising a memory coupled to the circuit.

Example 6 includes the subject matter of any of Examples 1-5, the processor further configured to: process data; provide power to the wearable system; and wirelessly connect to external devices.

Example 7 includes the subject matter of any of Examples 1-6, the processor further configured to: receive the input from the sensor; based on the input from the sensor, determine a relative location of the textile structure affixed on the user; and transmit, to an external computing system, the relative location.

Example 8 includes the subject matter of any of Examples 1-7, the processor configured to communicate with the external computing system via a radio frequency identification (“RFID”) signal.

Example 9 includes the subject matter of any of Examples 1-8, the processor configured to determine the relative location of the textile structure by determining one or more of a spatial location, configuration, position, or orientation of the textile structure affixed on the user.

Example 10 includes the subject matter of Example 1, the textile structure further comprising a power source providing power to the wearable system.

Example 11 includes the subject matter of any of Examples 1-10, the power source comprising an energy harvester and a near-field communication (“NFC”) coil to wirelessly power the wearable system.

Example 12 includes the subject matter of any of Examples 1-11, the power source comprising a battery and an energy harvester to power the wearable system.

Example 13 includes the subject matter of Example 1, wherein the functional device comprises a haptic feedback component.

Example 14 includes the subject matter of any of Examples 1-13, wherein the haptic feedback component comprises a shape-memory alloy actuator configured to apply a force, a vibration, a thermal sensation, or a motion as the response function.

Example 15 includes the subject matter of Example 1, wherein the functional device comprises a stiffness component.

Example 16 includes the subject matter of any of Examples 1-15, the stiffness component comprising a shape memory alloy configured to enable variable-stiffness as the response function.

Example 17 includes the subject matter of Example 1, wherein the functional device comprises a thermochromic display.

Example 18 includes the subject matter of any of Examples 1-17, the thermochromic display comprising a woven arrangement of thermochromic yarns configured to change color as the response function.

Example 19 includes the subject matter of Example 1, wherein the functional device comprises an audio device.

Example 20 includes the subject matter of Example 1, wherein the sensor comprises a capacitive touch sensor.

Example 21 includes the subject matter of Example 1, wherein the sensor comprises a strain sensor.

Example 22 includes the subject matter of Example 1, wherein the sensor comprises a pressure sensor.

Example 23 includes the subject matter of any of Examples 1-22, the pressure sensor comprising two electrodes separated by a piezoresistor for piezoresistive sensing.

Example 24 includes the subject matter of Example 1, wherein the sensor comprises a biosensor.

Example 25 includes the subject matter of any of Examples 1-24, the biosensor configured to detect one or more of a temperature, blood pressure, or pulse of the user.

Example 26 includes the subject matter of Example 1, wherein the sensor comprises an inertial movement unit.

Example 27 includes the subject matter of any of Examples 1-26, the inertial movement unit comprising a machine learning core to pre-process data and configured to measure one or more of an acceleration, orientation, and angular movement rate.

Example 28 includes the subject matter of Example 1, wherein the textile structure comprises a woven textile comprising one or more layers of interlaced materials with electrical connections between adjoining layers of the interlaced materials forming one or more electrical vertical interconnect access structures (“VIAS”) within the textile structure.

Example 29 includes the subject matter of any of Examples 1-28, the functional device being embedded within a particular layer of the one or more layers of interlaced materials.

Example 30 includes the subject matter of any of Examples 1-29, the sensor being embedded within a particular layer of the one or more layers of interlaced materials.

Example 31 includes the subject matter of any of Examples 1-30, the interlaced materials comprising a plain weave structure.

Example 32 includes the subject matter of any of Examples 1-31, the interlaced materials comprising a tapestry weave structure.

Example 33 includes the subject matter of any of Examples 1-32, the interlaced materials comprising a double weave structure.

Example 34 includes the subject matter of any of Examples 1-33, the interlaced materials comprising a lace weave structure.

Example 35 includes the subject matter of any of Examples 1-34, the interlaced materials comprising a weft material and a warp material, the weft material comprising a conductive material and the warp material comprising a non-conductive material.

Example 36 includes the subject matter of any of Examples 1-35, the interlaced materials comprising a weft material and a warp material, the warp material comprising a conductive material and the weft material comprising a non-conductive material.

Example 37 includes the subject matter of any of Examples 1-36, the warp material comprising a non-conductive textile material, an optical fiber, a thermochromic fiber, or a shape-memory alloy fiber.

Example 38 includes the subject matter of any of Examples 1-37, the textile structure further comprising: a plurality of functional devices; and a plurality of sensors, wherein the plurality of functional devices and the plurality of sensors interface between the one or more layers of interlaced materials using the one or more VIAS as the conductor.

Example 39 includes the subject matter of Example 1, wherein the textile structure comprises a knitted textile comprising one or more freeform integrated channels.

Example 40 includes the subject matter of any of Examples 1-39, wherein the one or more freeform integrated channels comprise one or more shape memory alloy (“SMA”) micro-springs.

Example 41 includes the subject matter of any of Examples 1-40, where the one or more SMA micro-springs are skin-shifting actuators when attached to a skin location of a user.

Example 42 includes the subject matter of any of Examples 1-41, wherein the one or more SMA micro-springs are self-shifting actuators when in close contact to a skin location of a user.

Example 43 includes the subject matter of Example 1, wherein the textile structure comprises a laced structure.

Example 44 includes the subject matter of Example 1, wherein the wearable system comprises configured as a patch, a bandage, a ring, a band, a garment, or a wearable textile.

Example 45 is a method, comprising: by a processor of a wearable device comprising a textile structure: receiving an input from one or more sensors of the wearable device; based on the input, determining a responsive function to be performed by one or more functional components of the wearable device; and transmitting, to each of the one or more functional components, instructions to perform the responsive function.

Example 46 includes the subject matter of Example 45, further comprising: by the processor of the wearable device comprising the textile structure: receiving data from one or more sensors of the wearable device; based on the received data, determining a position of the wearable device relative to a user of the wearable device; and transmitting, to an external computing system, the position of the wearable device.

Example 47 includes the subject matter of Example 45 or 46, wherein the processor communicates with the external computing system via a radio frequency identification (“RFID”) signal.

Example 48 includes the subject matter of any of Examples 45-47, wherein the processor determines the position of the wearable device by determining one or more of a spatial location, configuration, or orientation of the one or more sensors of the wearable device.

Example 49 is an affixable system, comprising: a textile structure configured to be affixed to a location, the textile structure comprising: one or more channels, one or more functional devices embedded within the one or more channels and configured to provide a response function, a sensor embedded within the textile structure, and a conductor embedded within the textile structure; and a circuit board connected to the one or more functional devices and the sensor by the conductor and the configured to receive an input from the sensor and to output a signal to the functional device to initiate the response function.

Example 50 includes the subject matter of Example 49, wherein the location is substantially cylindrical in shape.

Example 51 includes the subject matter of Example 49, wherein the location is associated with one or more of a user, an agricultural object, or a substantially cylindrical object.

Example 52 includes the subject matter of Example 49, the textile structure further comprising an adhesive layer configured to affix the textile structure to the location.

Example 53 includes the subject matter of Example 49, wherein the textile structure is affixed to the location by slipping over an object associated with the location.

Example 54 includes the subject matter of Example 49, wherein the textile structure comprises a knitted structure.

Example 55 includes the subject matter of Example 49, wherein the circuit board comprises a printed circuit board (“PCB”).

Example 56 includes the subject matter of Example 49, wherein the one or more functional devices are haptic feedback components.

Example 57 includes the subject matter of any of Examples 49-56, wherein the haptic feedback components are shape memory alloy (“SMA”) micro-springs.

Example 58 includes the subject matter of any of Examples 49-57, wherein the haptic feedback components are configured to apply one or more of a compression, a pinch, a brush, or a twist as the response function based on the input from the sensor.

Example 59 includes the subject matter of Example 49, wherein the sensor comprises a capacitive touch sensor.

Example 60 includes the subject matter of Example 49, wherein the one or more channels are configured in a linear shape.

Example 61 includes the subject matter of Example 49, wherein the one or more channels are configured in a free-form curve shape.

Example 62 includes the subject matter of Example 49, wherein the one or more channels are configured in a closed curve shape.

Example 63 includes the subject matter of Example 49, wherein the one or more channels intersect.

Example 64 includes the subject matter of Example 49, wherein the textile structure comprises a sleeve.

Example 65 includes the subject matter of any of Examples 49-64, wherein the sleeve is configured to affix to a cylindrical object by slipping over the cylindrical object.

Example 66 includes the subject matter of any of Examples 49-65, the sleeve comprising a latching mechanism such that the sleeve can be affixed to a cylindrical object.

Example 67 includes the subject matter of Example 49, wherein the one or more functional devices are pneumatic actuators.

Example 68 includes the subject matter of any of Examples 49-67, wherein the pneumatic actuators are configured to lengthen as the response function based on the input from the sensor.

Example 69 includes the subject matter of any of Examples 49-68, the textile structure configured for motion relative to the location that the textile structure is affixed in response to a lengthening of the pneumatic actuators.

Example 70 includes the subject matter of any of Examples 49-69, the textile structure configured to apply a normal force to a surface of the location that the textile structure is affixed while in motion.

Example 71 includes the subject matter of any of Examples 49-70, wherein the pneumatic actuators are connected to a pressure source.

Example 72 includes the subject matter of any of Examples 49-71, wherein the textile structure comprises a knitted structure comprising a base layer and an inner layer.

Example 73 includes the subject matter of any of Examples 49-72, the base layer comprising an elastic material conformable to the location that the textile structure is affixed.

Example 74 includes the subject matter of any of Examples 49-73, the inner layer comprising one or more rows of curved scales, wherein the one or more rows of curved scales are configured to engage with a surface of the location to which the textile structure is affixed such that the textile structure moves relative to the surface in response to a lengthening of the pneumatic actuators.

Example 75 includes the subject matter of Example 49, wherein the one or more functional devices are fluidic yarn actuators.

Example 76 includes the subject matter of Example 49, wherein the sensor comprises a microphone.

Example 77 includes the subject matter of Example 49, wherein the sensor comprises a water sensor.

Example 78 includes the subject matter of Example 49, wherein the sensor comprises a velocity sensor.

What is claimed is:

1. A wearable system, comprising:
a textile structure configured to be affixed to a location on a user, the textile structure comprising:
a functional device embedded within the textile structure and enabled to provide a response function,
a sensor embedded within the textile structure, and
a conductor embedded within the textile structure connecting the functional device and the sensor; and
a circuit configured to receive an input from the sensor and to output a signal to the functional device to initiate the response function.

2. The wearable system of claim 1, the textile structure further comprising an adhesive layer configured to affix the textile structure to the location on the user.

3. The wearable system of claim 2, wherein the adhesive layer comprises a polyvinyl alcohol adhesive.

4. The wearable system of claim 1, the textile structure further comprising a processor coupled to the circuit, the processor configured to:
receive the input from the sensor; and
output the signal to the functional device to initiate the response function.

5. The wearable system of claim 4, the textile structure further comprising a memory coupled to the circuit.

6. The wearable system of claim 4, the processor further configured to:
process data;
provide power to the wearable system; and
wirelessly connect to external devices.

7. The wearable system of claim 6, the processor further configured to:
receive the input from the sensor;
based on the input from the sensor, determine a relative location of the textile structure affixed on the user; and
transmit, to an external computing system, the relative location.

8. The wearable system of claim 7, the processor configured to communicate with the external computing system via a radio frequency identification (“RFID”) signal.

9. The wearable system of claim 7, the processor configured to determine the relative location of the textile structure by determining one or more of a spatial location, configuration, position, or orientation of the textile structure affixed on the user.

10. The wearable system of claim 1, the textile structure further comprising a power source providing power to the wearable system.

11. The wearable system of claim 10, the power source comprising an energy harvester and a near-field communication (“NFC”) coil to wirelessly power the wearable system.

12. The wearable system of claim 10, the power source comprising a battery and an energy harvester to power the wearable system.

13. The wearable system of claim 1, wherein the functional device comprises a haptic feedback component.

14. The wearable system of claim 13, wherein the haptic feedback component comprises a shape-memory alloy actuator configured to apply a force, a vibration, a thermal sensation, or a motion as the response function.

15. The wearable system of claim 1, wherein the functional device comprises a stiffness component.

16. The wearable system of claim 15, the stiffness component comprising a shape memory alloy configured to enable variable-stiffness as the response function.

17. The wearable system of claim 1, wherein the functional device comprises a thermochromic display.

18. The wearable system of claim 17, the thermochromic display comprising a woven arrangement of thermochromic yarns configured to change color as the response function.

19. The wearable system of claim 1, wherein the functional device comprises an audio device.

20. The wearable system of claim 1, wherein the sensor comprises a capacitive touch sensor.

21. The wearable system of claim 1, wherein the sensor comprises a strain sensor.

22. The wearable system of claim 1, wherein the sensor comprises a pressure sensor.

23. The wearable system of claim 22, the pressure sensor comprising two electrodes separated by a piezoresistor for piezoresistive sensing.

24. The wearable system of claim 1, wherein the sensor comprises a biosensor.

25. The wearable system of claim 24, the biosensor configured to detect one or more of a temperature, blood pressure, or pulse of the user.

26. The wearable system of claim 1, wherein the sensor comprises an inertial movement unit.

27. The wearable system of claim 26, the inertial movement unit comprising a machine learning core to pre-process data and configured to measure one or more of an acceleration, orientation, and angular movement rate.

28. The wearable system of claim 1, wherein the textile structure comprises a woven textile comprising one or more layers of interlaced materials with electrical connections between adjoining layers of the interlaced materials forming one or more electrical vertical interconnect access structures (“VIAS”) within the textile structure.

29. The wearable system of claim 28, the functional device being embedded within a particular layer of the one or more layers of interlaced materials.

30. The wearable system of claim 28, the sensor being embedded within a particular layer of the one or more layers of interlaced materials.

31. The wearable system of claim 28, the interlaced materials comprising a plain weave structure.

32. The wearable system of claim 28, the interlaced materials comprising a tapestry weave structure.

33. The wearable system of claim 28, the interlaced materials comprising a double weave structure.

34. The wearable system of claim 28, the interlaced materials comprising a lace weave structure.

35. The wearable system of claim 28, the interlaced materials comprising a weft material and a warp material, the weft material comprising a conductive material and the warp material comprising a non-conductive material.

36. The wearable system of claim 28, the interlaced materials comprising a weft material and a warp material, the warp material comprising a conductive material and the weft material comprising a non-conductive material.

37. The wearable system of claim 35, the warp material comprising a non-conductive textile material, an optical fiber, a thermochromic fiber, or a shape-memory alloy fiber.

38. The wearable system of claim 28, the textile structure further comprising:
a plurality of functional devices; and
a plurality of sensors, wherein the plurality of functional devices and the plurality of sensors interface between the one or more layers of interlaced materials using the one or more VIAS as the conductor.

39. The wearable system of claim 1, wherein the textile structure comprises a knitted textile comprising one or more freeform integrated channels.

40. The wearable system of claim 39, wherein the one or more freeform integrated channels comprise one or more shape memory alloy (“SMA”) micro-springs.

41. The wearable system of claim 40, where the one or more SMA micro-springs are skin-shifting actuators when attached to a skin location of a user.

42. The wearable system of claim 40, wherein the one or more SMA micro-springs are self-shifting actuators when in close contact to a skin location of a user.

43. The wearable system of claim 1, wherein the textile structure comprises a laced structure.

44. The wearable system of claim 1, wherein the wearable system comprises configured as a patch, a bandage, a ring, a band, a garment, or a wearable textile.

45. A method, comprising:
by a processor of a wearable device comprising a textile structure:
receiving an input from one or more sensors of the wearable device;
based on the input, determining a responsive function to be performed by one or more functional components of the wearable device; and
transmitting, to each of the one or more functional components, instructions to perform the responsive function.

46. The method of claim 45, further comprising:
by the processor of the wearable device comprising the textile structure:
receiving data from one or more sensors of the wearable device;
based on the received data, determining a position of the wearable device relative to a user of the wearable device; and
transmitting, to an external computing system, the position of the wearable device.

47. The method of claim 46, wherein the processor communicates with the external computing system via a radio frequency identification (“RFID”) signal.

48. The method of claim 46, wherein the processor determines the position of the wearable device by determining one or more of a spatial location, configuration, or orientation of the one or more sensors of the wearable device.

49. An affixable system, comprising:
a textile structure configured to be affixed to a location, the textile structure comprising:
one or more channels,
one or more functional devices embedded within the one or more channels and configured to provide a response function,
a sensor embedded within the textile structure, and
a conductor embedded within the textile structure; and
a circuit board connected to the one or more functional devices and the sensor by the conductor and the configured to receive an input from the sensor and to output a signal to the functional device to initiate the response function.

50. The affixable system of claim 49, wherein the location is substantially cylindrical in shape.

51. The affixable system of claim 49, wherein the location is associated with one or more of a user, an agricultural object, or a substantially cylindrical object.

52. The affixable system of claim 49, the textile structure further comprising an adhesive layer configured to affix the textile structure to the location.

53. The affixable system of claim 49, wherein the textile structure is affixed to the location by slipping over an object associated with the location.

54. The affixable system of claim 49, wherein the textile structure comprises a knitted structure.

55. The affixable system of claim 49, wherein the circuit board comprises a printed circuit board (“PCB”).

56. The affixable system of claim 49, wherein the one or more functional devices are haptic feedback components.

57. The affixable system of claim 56, wherein the haptic feedback components are shape memory alloy (“SMA”) micro-springs.

58. The affixable system of claim 56, wherein the haptic feedback components are configured to apply one or more of a compression, a pinch, a brush, or a twist as the response function based on the input from the sensor.

59. The affixable system of claim 49, wherein the sensor comprises a capacitive touch sensor.

60. The affixable system of claim 49, wherein the one or more channels are configured in a linear shape.

61. The affixable system of claim 49, wherein the one or more channels are configured in a free-form curve shape.

62. The affixable system of claim 49, wherein the one or more channels are configured in a closed curve shape.

63. The affixable system of claim 49, wherein the one or more channels intersect.

64. The affixable system of claim 49, wherein the textile structure comprises a sleeve.

65. The affixable system of claim 64, wherein the sleeve is configured to affix to a cylindrical object by slipping over the cylindrical object.

66. The affixable system of claim 64, the sleeve comprising a latching mechanism such that the sleeve can be affixed to a cylindrical object.

67. The affixable system of claim 49, wherein the one or more functional devices are pneumatic actuators.

68. The affixable system of claim 67, wherein the pneumatic actuators are configured to lengthen as the response function based on the input from the sensor.

69. The affixable system of claim 67, the textile structure configured for motion relative to the location that the textile structure is affixed in response to a lengthening of the pneumatic actuators.

70. The affixable system of claim 69, the textile structure configured to apply a normal force to a surface of the location that the textile structure is affixed while in motion.

71. The affixable system of claim 67, wherein the pneumatic actuators are connected to a pressure source.

72. The affixable system of claim 67, wherein the textile structure comprises a knitted structure comprising a base layer and an inner layer.

73. The affixable system of claim 72, the base layer comprising an elastic material conformable to the location that the textile structure is affixed.

74. The affixable system of claim 72, the inner layer comprising one or more rows of curved scales, wherein the one or more rows of curved scales are configured to engage with a surface of the location to which the textile structure is affixed such that the textile structure moves relative to the surface in response to a lengthening of the pneumatic actuators.

75. The affixable system of claim 49, wherein the one or more functional devices are fluidic yarn actuators.

76. The affixable system of claim 49, wherein the sensor comprises a microphone.

77. The affixable system of claim 49, wherein the sensor comprises a water sensor.

78. The affixable system of claim 49, wherein the sensor comprises a velocity sensor.
